(19) United States
(12) Patent Application Publication
(10) Pub. No.: US 2024/0105727 A1
(43) Pub. Date: Mar. 28, 2024

(54) Vertical Transistor Cell Structures Utilizing Topside and Backside Resources

(71) Applicant: Apple Inc., Cupertino, CA (US)

(72) Inventors: Xin Miao, Saratoga, CA (US); Praveen Raghavan, Cupertino, CA (US); Thomas Hoffmann, Los Gatos, CA (US); Saurabh P. Sinha, Austin, TX (US)

(21) Appl. No.: 18/448,746

(22) Filed: Aug. 11, 2023

Related U.S. Application Data
(60) Provisional application No. 63/376,802, filed on Sep. 23, 2022.

(51) Int. Cl. H01L 27/118

(52) U.S. Cl. CPC H01L 27/11807; H01L 2027/11851; H01L 2027/11875; H01L 2027/11881

(57) ABSTRACT

Various structures that implement topside metal routing and backside metal routing in combination with vertical transistors are disclosed. The various structures include cells that form inverter devices, NAND devices, and MUX (multiplexer) devices. The disclosed cells include two or four vertical transistors with various connections made to the transistors that include either connected gate logic for inverter and NAND devices or disconnected gate logic for MUX devices.

### PRIORITY CLAIM

The present application claims priority to U.S. Provisional App. No. 63/376,802, entitled “Vertical Transistors With Backside Power Delivery,” filed Sep. 23, 2022, the disclosure of which is incorporated by reference herein in its entirety.

### BACKGROUND

### Technical Field

Embodiments described herein relate to power and signal routing for semiconductor devices. More particularly, embodiments described herein relate to power and signal routing for vertical transistors.

### Description of the Related Art

Standard cells are groups of transistors, passive structures, and interconnect structures that can provide logic functions, storage functions, etc. Current trends in standard cell methodology are towards reducing the size of standard cells while increasing the complexity (e.g., circuit density and number of components or transistors) within standard cells. As standard cell designs become smaller, however, it becomes more difficult to provide access (e.g., connections) to components within the standard cells and within design/manufacturing constraints of standard cells.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a perspective representation of a contemplated vertical transistor device, according to some embodiments.

FIG. 2 depicts a perspective representation of another contemplated vertical transistor device, according to some embodiments.

FIG. 3 depicts a perspective view representation of an inverter cell construction, according to some embodiments.

FIG. 4 depicts a topside plan view representation of an inverter cell construction, according to some embodiments.

FIG. 5 depicts a backside plan view representation of an inverter cell construction, according to some embodiments.

FIG. 6 depicts a cross-sectional representation of an inverter cell construction, according to some embodiments, along line 6-6 shown in FIG. 4.

FIG. 7 depicts a cross-sectional representation of an inverter cell construction, according to some embodiments, along line 7-7 shown in FIG. 4.

FIG. 8 depicts a perspective view representation of a NAND cell construction, according to some embodiments.

FIG. 9 depicts a topside plan view representation of a NAND cell construction, according to some embodiments.

FIG. 10 depicts a backside plan view representation of the NAND cell construction, according to some embodiments.

FIG. 11 depicts a cross-sectional representation of a NAND cell construction, according to some embodiments, along line 11-11 shown in FIG. 9.

FIG. 12 depicts a cross-sectional representation of a NAND cell construction, according to some embodiments, along line 12-12 shown in FIG. 9.

FIG. 13 depicts a perspective view representation of a MUX cell construction, according to some embodiments.

FIG. 14 depicts a topside plan view representation of a MUX cell construction, according to some embodiments.

FIG. 15 depicts a backside plan view representation of a MUX cell construction, according to some embodiments.

FIG. 16 depicts a cross-sectional representation of a MUX cell construction, according to some embodiments, along line 16-16 shown in FIG. 14.

FIG. 17 depicts a cross-sectional representation of a MUX cell construction, according to some embodiments, along line 17-17 shown in FIG. 14.

FIG. 18 depicts a perspective view representation of a device, according to some embodiments.

FIG. 19 depicts a cross-sectional representation of a device, according to some embodiments, along line 19-19 shown in FIG. 51.

FIG. 20 depicts a perspective view representation of an inverter cell construction, according to some embodiments.

FIG. 21 depicts a topside plan view representation of the inverter cell construction, according to some embodiments.

FIG. 22 depicts a backside plan view representation of the inverter cell construction, according to some embodiments.

FIG. 23 depicts a cross-sectional representation of the inverter cell construction, according to some embodiments.

FIG. 24 depicts a cross-sectional representation of the inverter cell construction, according to some embodiments.

FIG. 25 depicts a perspective view representation of a NAND cell construction, according to some embodiments.

FIG. 26 depicts a topside plan view representation of the NAND cell construction, according to some embodiments.

FIG. 27 depicts a backside plan view representation of the NAND cell construction, according to some embodiments.

FIG. 28 depicts a cross-sectional representation of the NAND cell construction, according to some embodiments.

FIG. 29 depicts a cross-sectional representation of the NAND cell construction, according to some embodiments.

FIG. 30 depicts a perspective view representation of the MUX cell construction, according to some embodiments.

FIG. 31 depicts a topside plan view representation of a MUX cell construction, according to some embodiments.

FIG. 32 depicts a backside plan view representation of the MUX cell construction, according to some embodiments.

FIG. 33 depicts a cross-sectional representation of the MUX cell construction, according to some embodiments.

FIG. 34 is a block diagram of one embodiment of an example system.

Although the embodiments disclosed herein are susceptible to various modifications and alternative forms, specific embodiments are shown by way of example in the drawings and are described herein in detail. It should be understood, however, that drawings and detailed description thereto are not intended to limit the scope of the claims to the particular forms disclosed. On the contrary, this application is intended to cover all modifications, equivalents and alternatives falling within the spirit and scope of the disclosure of the present application as defined by the appended claims.

### DETAILED DESCRIPTION OF EMBODIMENTS

The present disclosure is directed to the implementation of vertical transistors in integrated circuit cells (e.g., standard cells) through the utilization of connections to both topside metal layers and backside metal layers. The topside and backside metal layers may provide routing (e.g., paths) for control signals and/or power signals. The disclosed embodiments provide connections for vertical transistors in an integrated circuit cell to either control signal routing or power signal routing in either the topside or the backside metal layer. As used herein, the term “standard cell” refers to a group of transistor structures, passive structures, and interconnect structures formed on a substrate to provide logic or storage functions that are standard for a variety of implementations. For example, an individual standard cell may be one cell in a library of multiple cells from which various suitable cells may be selected to implement a specific cell design. Integrated circuit cells may also include custom circuit design cells that are individually designed for a particular implementation. Embodiments of circuit design cells described herein may be implemented in various implementations of logic integrated circuits or memory integrated circuits.

Many current designs of cells provide connections and routing for power or signals to transistors or other structures in areas above the transistors. For example, the connections and routing for power or signals may be provided in topside layers of the device. As used herein, the term “topside” refers to areas in a device that are vertically above an active layer of the device (e.g., above a transistor region of the device when viewed in a typical cross-sectional view). For example, topside may refer to components such as contacts or layers that are above a transistor region in a vertical dimension, as depicted in the figures and described herein. In some instances, the term “frontside” may be used interchangeably with the term “topside”.

Some recent developments for designs of standard cells move connections and routing for power connections to metal layers below the transistors. For example, the connections and routing for power may be provided in the backside layers of the device. As used herein, the term “backside” refers to areas in a device that are vertically below an active layer of the device (e.g., below a transistor region of the device when viewed in a typical cross-sectional view). For example, backside may refer to components such as contacts or layers that are below a transistor region in a vertical dimension, as depicted in the figures and described herein. It is noted that as used herein, backside elements located below an active layer may be situated above, within, or below a silicon substrate on which the active layer is manufactured. That is, as used herein, “backside” is relative to the active layer, rather than the silicon substrate. As used herein, the term “routing” refers to any combination of metal vias, metal wires, metal traces, etc. that provide a path/route between two structures. Additional embodiments may be contemplated where the metal in “routing” is replaced with an alternative conductive material. For instance, the metal in “routing” may be replaced with a superconductor material, a semiconductor material, or a non-metal conductor.

A recent development in transistor design is the implementation of vertical transistors where the cells have vertical transport through vertically displaced source/drain regions and a gate positioned vertically in between the source/drain regions. Current vertical transistor designs typically include wide frontside (e.g., topside) power rails at the boundaries of the cell for power delivery. These wide power rails, however, contribute to an increased and large standard cell height. The larger standard cell height reduces the area efficiency of the vertical transistor while also reducing available connectivity and performance of the transistor.

The present disclosure contemplates various embodiments that utilize backside power routing in vertical transistor designs to reduce scaling, provide better connectivity, and provide better performance of the transistors. Certain embodiments disclosed herein have four broad elements: 1) a pair of vertical transistors in an integrated circuit cell; 2) a topside metal layers above the transistor regions of the vertical transistors with signal routing, 3) a backside metal layer below the transistor regions with power routing, and 4) a metal contact layer between the backside metal layer and source/drain regions of the transistors. In certain embodiments, the transistors are complementary transistors. In some embodiments, vias couple power routing in the backside metal layer to the metal contact layer. In some embodiments, a second pair of vertical transistors may be included in the cell. Additional implementations of gate vias, fins, contact vias, and various other connections and routings may also be contemplated in various embodiments.

The present disclosure further contemplates various embodiments of vertical transistor designs that utilize backside power routing in combination with cell height direction (e.g., vertical cell direction) signal routing in the topside layers to reduce scaling, provide better connectivity, and provide better performance of the transistors. Certain embodiments disclosed herein have four broad elements: 1) a pair of vertical transistors; 2) a topside metal layer above the transistor regions of the vertical transistors with parallel signal routing in a first direction, 3) a gate via coupling signal routing in the topside metal layer to at least one of the gates of the transistors, and 4) parallel power routing in the backside metal layer in a second direction perpendicular to the first direction. In certain embodiments, at least one of the transistors is coupled to the power routing. In some embodiments, a gate bridge connects gates of the transistors. The gate bridge may be connected to the signal routing by the gate via. The signal routing may include both input and output signal routing with input signal routing coupled to the gates and output signal routing coupled to the source/drain regions of the transistors. In some embodiments, a second pair of vertical transistors may be included in the cell. Additional implementations of gate vias, fins, contact vias, and various other connections and routings may also be contemplated in various embodiments.

In various embodiments, control signal and power signal connections are made using various contacts or vias to implement logic associated with specific integrated circuit devices having multiple vertical transistors for the cell constructions described herein. For instance, examples of an inverter device, a NAND device, and a MUX device that may be implemented based on the vertical transistor cell construction are described below. Embodiments of various possible connections for control signals and voltage signals to the vertical transistors within the cell constructions are also described. A person with knowledge in the art would understand that combinations of these various possible connections may be implemented to generate many different desired circuits based on the vertical transistor structure within the cell constructions disclosed herein.

In short, the present inventors have recognized that the implementation of backside routing for power connections in combination with vertical transistors provides various opportunities for construction of specific transistor designs with reduced scaling. Additionally, various techniques are implemented to provide specific routing for control signal and power routing within the cell constructions with vertical transistors described herein. With implementation of the various disclosed techniques, vertical transistor cell constructions that provide improved performance in a small scale factor are contemplated.

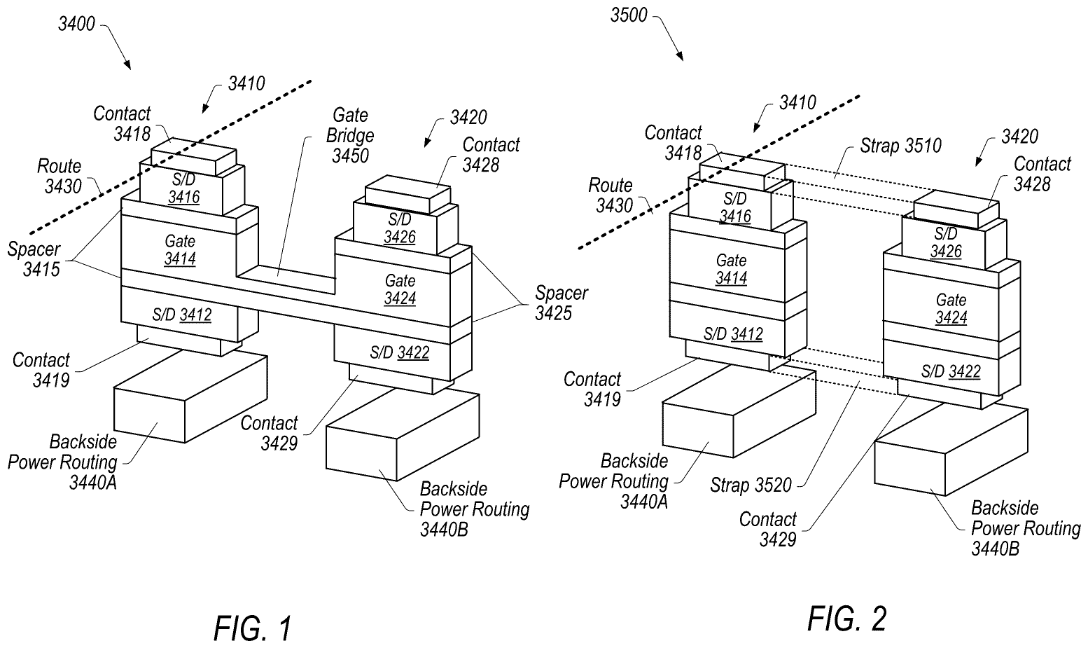

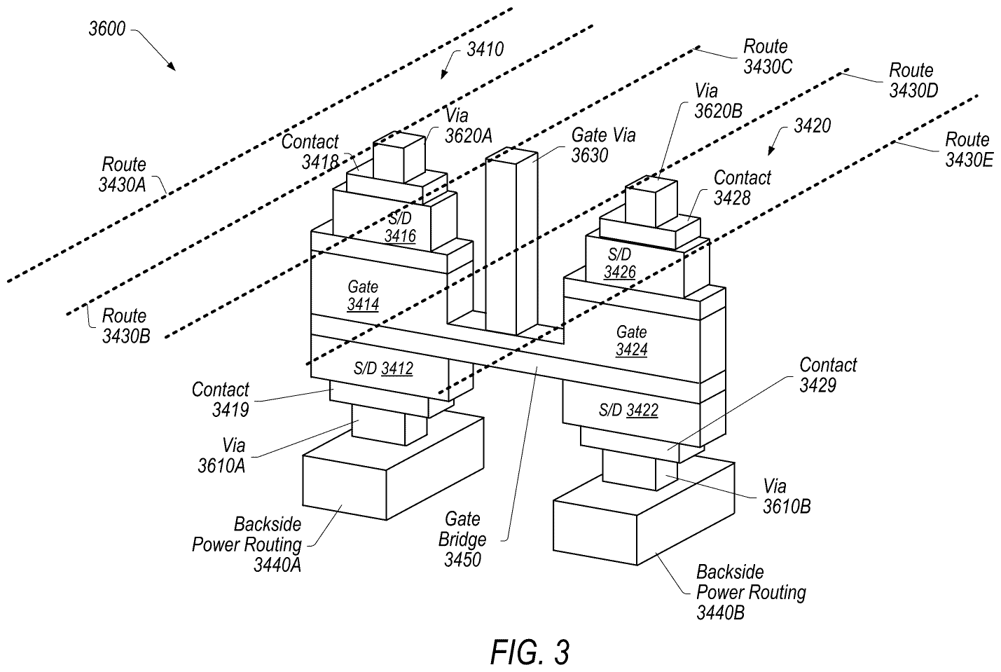

FIG. 1 depicts a perspective representation of a contemplated vertical transistor device, according to some embodiments. FIG. 2 depicts a perspective representation of another contemplated vertical transistor device, according to some embodiments. It should be noted that device 3400, shown in FIG. 1, and device 3500, shown in FIG. 2, are generic representations of vertical transistor-based device structures without depiction of various connections that can be made to the structures. Example embodiments of connected structures are further disclosed herein below with respect to FIGS. 3-19.

In the illustrated embodiment of FIG. 1, device 3400 includes two vertical transistors 3410, 3420. In certain embodiments, transistors 3410, 3420 are complementary types of transistors. For instance, transistor 3410 is a PMOS transistor and transistor 3420 is an NMOS transistor. Transistor 3410 includes lower source/drain region 3412, gate 3414, and upper source/drain region 3416. Similarly, transistor 3420 includes lower source/drain region 3422, gate 3424, and upper source/drain region 3426. In some embodiments, gate 3414 and gate 3424 are fin-type gates. In various embodiments, gate 3414 includes gate spacers 3415 and gate 3424 includes gate spacers 3425. Gate spacers 3415, 3425 are not labelled in the remaining figures for simplicity in the drawings.

As depicted in FIG. 1, the lower source/drain regions, the gates, and the upper source/drain regions are stacked in the vertical dimension of the transistors. Further as depicted, transistor 3410 and transistor 3420 are parallel and have a spacing (e.g., distance) between them in the horizontal direction (e.g., the horizontal dimension) of device 3400.

In certain embodiments, transistor 3410 includes upper contact 3418 coupled to upper source/drain region 3416 and transistor 3420 includes upper contact 3428 coupled to upper source/drain region 3426. Contact 3418 and contact 3428 may be, for example, metal contacts for contacting various resources in a first metal layer positioned above transistor 3410 and transistor 3420. For example, as shown in FIG. 1, contact 3418 may be routed to a resource by route 3430 (e.g., a routing shown by the dotted line). Route 3430 may be, for example, a metal layer route path in a first metal layer above transistor 3410 and transistor 3420. It should be noted that the dotted line depiction of route 3430 is provided as example of one resource (e.g., routing) in the metal layer and that the metal layer may include multiple resources (e.g., multiple routings). Additionally, only the first metal layer above transistor 3410 and transistor 3420 is depicted and there may be multiple additional metal routing above route 3430.

In various embodiments, transistor 3410 includes lower contact 3419 coupled to lower source/drain region 3412 and transistor 3420 includes lower contact 3429 coupled to lower source/drain region 3422. Contacts 3419, 3429 may be, for example, metal contacts. Contacts 3419, 3429 may be utilized to route to backside power routing layers (e.g., backside power routing 3440A or backside power routing 3440B, as shown in FIG. 1 and described herein) or to route to various other resources within device 3400.

In certain embodiments, device 3400 includes a backside power layer. In the illustrated embodiment of FIG. 1, the backside power layer includes backside power routing 3440A and backside power routing 3440B. Routing 3440A and routing 3440B may, for example, provided routing to/from power source (e.g., Vdd) and power ground (e.g., Vss) resources for device 3400.

In various embodiments, gate 3414 and gate 3424 are interconnected by gate bridge 3450. Gate bridge 3450 may be formed, for example, by extension of the gate material of gate 3414 and gate 3424 to couple the gates together. In some embodiments, gate bridge 3450 may be formed by a single extension of gate material from either gate 3414 or gate 3424 that is extended to the other gate. Gate bridge 3450 may also include extension of material for gate spacers. Gate bridge 3450 merges gate 3414 and gate 3424 for implementation of transistor 3410 and transistor 3420 in various embodiments of CMOS devices, some examples of which are described herein. Various embodiments may also be contemplated where gate 3414 and/or gate 3424 extend in other directions. For instance, a gate may include an extension that extends towards an outer boundary of device 3400 (e.g., towards an outer boundary of the cell structure in an opposite direction of gate bridge 3450).

In the illustrated embodiment of FIG. 2, device 3500 does not have a gate bridge connecting gate 3414 in transistor 3410 and gate 3424 in transistor 3420. Various techniques for connecting transistor 3410 and transistor 3420 may be contemplated without the gate bridge. For instance, in one contemplated embodiment, contact 3418 and contact 3428 may be connected by strap 3510. Strap 3510 may be, for example, a metal strap. In some embodiments, contact 3418, contact 3428, and strap 3510 may be formed as a single contact (e.g., a single strap connecting upper source/drain region 3416 and upper source/drain region 3426). Various embodiments may also be contemplated where strap 3510 extends in another direction from one of contacts 3418, 3428. For instance, strap 3510 may extend perpendicular to the depicted embodiment towards another vertical transistor or resource in device 3500.

In another contemplated embodiment, contact 3419 and contact 3429 may be connected by strap 3520. Strap 3520 may also be a metal strap. In some embodiments, strap 3520 is formed as a single contact along with contact 3419 and contact 3429. For example, strap 3520, contact 3419, and contact 3429 may be part of a single metal contact plate formed in the contact layer. Various embodiments may also be contemplated where contact 3419 and/or contact 3429 extends outwards from the bottoms of transistors 3410, 3420. For instance, a contact may have a portion that extends towards an outer boundary of device 3500 (e.g., towards an outer boundary of the cell structure).

It should be understood that while device 3400, shown in FIG. 1, and device 3500, shown in FIG. 2, are depicted with various connection structures separately, embodiments may be contemplated where structures from device 3400 are combined with structures from device 3500 in a cell design. For instance, a device may be contemplated that includes both gate bridge 3450 and one or both of strap 3510 and strap 3520. Various example device cell constructions are now described as example based on device 3400 and/or device 3500. It should be noted that the various device cell constructions are provided as example and that various additional device cell constructions may be implemented based on the description herein.

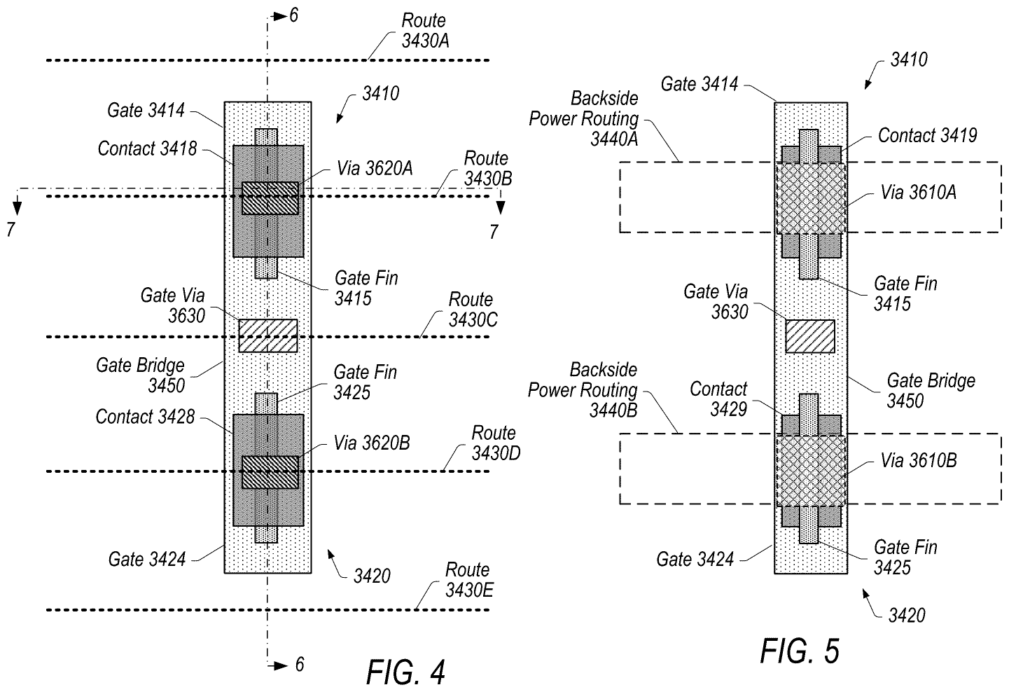

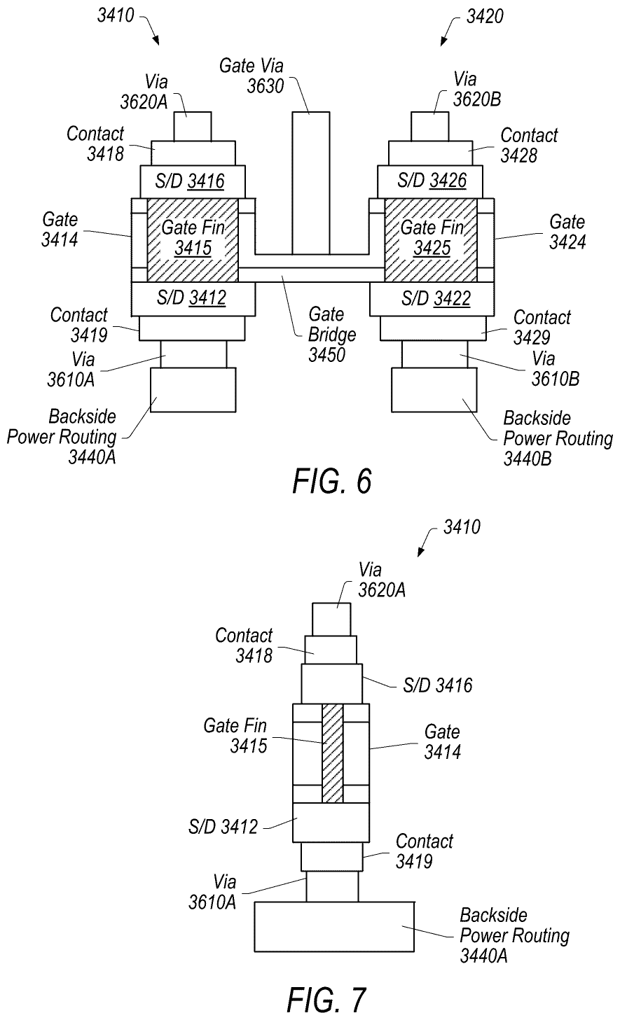

FIGS. 3-7 depict representations of an inverter cell construction, according to some embodiments. FIG. 3 depicts a perspective view representation of the inverter cell construction, according to some embodiments. FIG. 4 depicts a topside plan view representation of the inverter cell construction, according to some embodiments. FIG. 5 depicts a backside plan view representation of the inverter cell construction, according to some embodiments. FIG. 6 depicts a cross-sectional representation of the inverter cell construction, according to some embodiments, along line 6-6 shown in FIG. 4 (e.g., along the gate bridge). FIG. 7 depicts a cross-sectional representation of the inverter cell construction, according to some embodiments, along line 7-7 shown in FIG. 4 (e.g., perpendicular to the gate fin of transistor 3410).

Inverter cell device 3600 may be derived from the structure of device 3400, shown in FIG. 1. In the illustrated embodiment of FIGS. 3-7, device 3600 includes vertical transistor 3410 and vertical transistor 3420. Transistor 3410 includes lower source/drain region 3412, gate 3414, upper source/drain region 3416, upper contact 3418, and lower contact 3419. Transistor 3420 includes lower source/drain region 3422, gate 3424, upper source/drain region 3426, upper contact 3428, and lower contact 3429. In the illustrated embodiment of device 3600, transistor 3410 is a PMOS transistor and transistor 3420 is an NMOS transistor.

In certain embodiments, device 3600 includes backside vias 3610A, 3610B. Backside via 3610A is coupled to lower source/drain region 3412 through lower contact 3419. Backside via 3610A couples lower source/drain region 3412 to backside power routing 3440A. For device 3600, backside power routing 3440A provides power supply (e.g., Vdd) to lower source/drain region 3412 and transistor 3410. Backside via 3610B is coupled to lower source/drain region 3422 through lower contact 3429. Backside via 3610B couples lower source/drain region 3422 to backside power routing 3440B. For device 3600, backside power routing 3440B provides ground supply (e.g., Vss) to lower source/drain region 3422 and transistor 3420.

In various embodiments, device 3600 includes topside vias 3620A, 3620B. Topside via 3620A may be coupled to upper source/drain region 3416 through upper contact 3418 and topside via 3620B may be coupled to upper source/drain region 3426 through upper contact 3428. Topside vias 3620A, 3620B may provide connection to signal routing resources (e.g., routes 3430A-E) in a first metal layer above transistor 3410 and transistor 3420. For example, in the illustrated embodiment, topside via 3620A is coupled to route 3430B and topside via 3620B is coupled to route 3430D. Routes 3430B and 3430D may provide routes for output signals from transistor 3410 and transistor 3420, respectively.

In certain embodiments, a route for an input signal to transistor 3410 and transistor 3420 is provided by route 3430C. As shown in FIGS. 3 and 4, route 3430C is coupled to gate via 3630, which is coupled to gate bridge 3450. Thus, gate via 3630 provides connection between route 3430C (e.g., the input signal route) and both gate 3414 in transistor 3410 and gate 3424 in transistor 3420. With the connections to the input signal route, the output signal routes, and the power supply/ground routes, transistor 3410 and transistor 3420 are connected to form the inverter cell device 3600.

It should be noted that while FIGS. 3 and 4 depict five routes 3430A-E in the first metal layer above transistor 3410 and transistor 3420, the first metal layer may include additional routes. Further, additional metal layers may be positioned above the first metal layer and provide various connections to either the first metal layer or device 3600. For example, in one embodiment, a metal layer above the first metal layer may include a strap (or other connector) coupling route 3430B and route 3430D such that the outputs of transistor 3410 and transistor 3420 are merged together into a single output. Additionally, while two backside power routings are shown (e.g., routing 3440A and routing 3440B), the backside power layer may include additional routings (e.g., routings for other power and signal resources).

The topside and backside plan views of device 3600 shown in FIGS. 4 and 5 further depict gate fins that may be present in the gates of the transistors. For example, gate fin 3415 is the gate fin for gate 3414 and gate fin 3425 is the gate fin for gate 3424. Gate fin 3415 and gate fin 3425 are also shown in the cross-sectional representation of device 3600 in FIG. 6 and gate fin 3415 is shown in the cross-sectional representation of transistor 3410 in FIG. 7. Note that the cross-section representation of FIG. 7 is perpendicular to the gate fin of transistor 3410, which is the direction of route 3430B, shown in FIGS. 3 and 4.

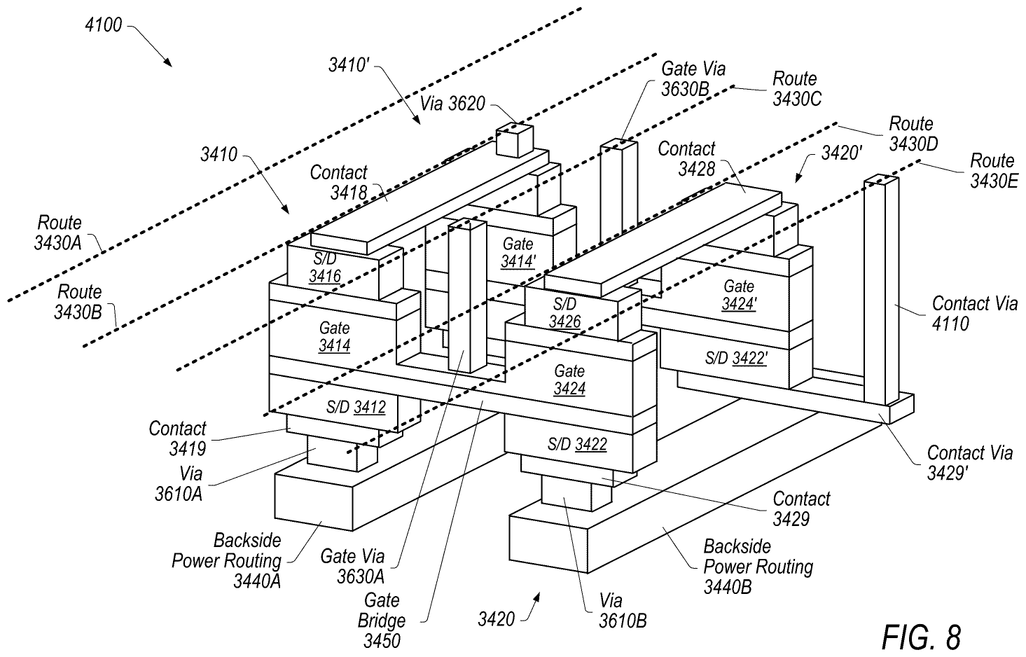

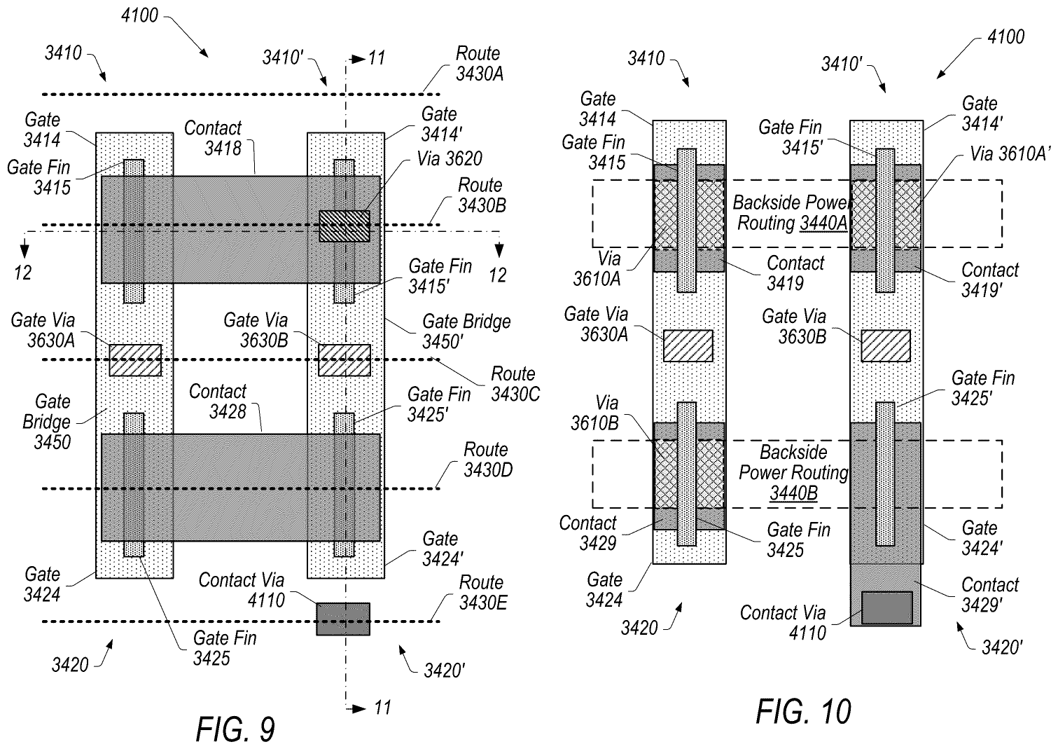

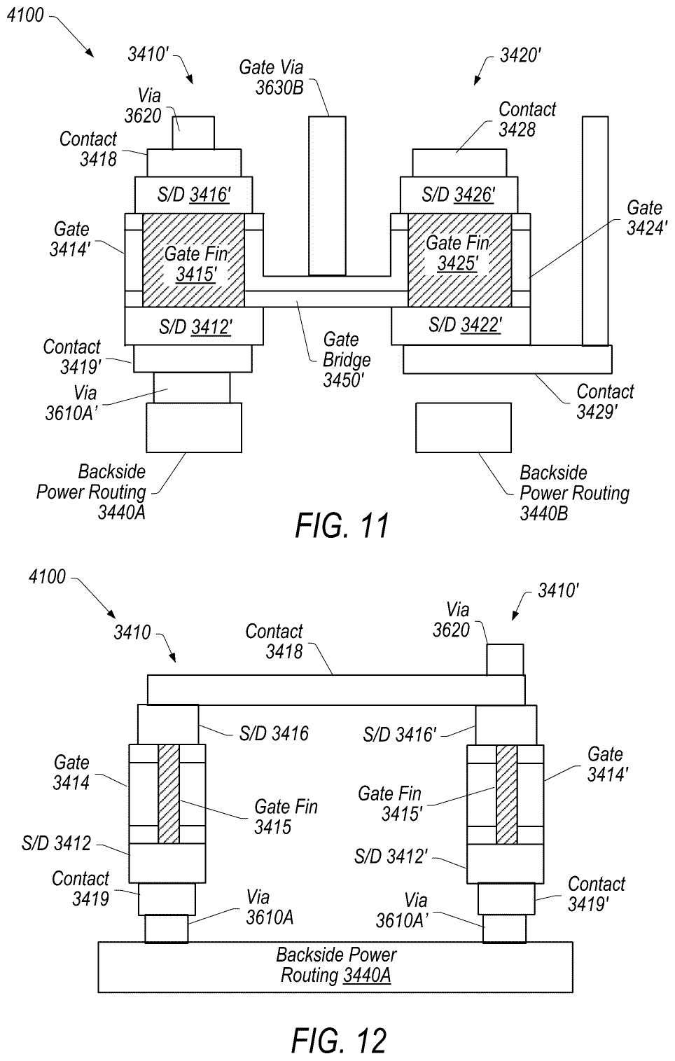

FIGS. 8-12 depict representations of a NAND cell construction, according to some embodiments. FIG. 8 depicts a perspective view representation of the NAND cell construction, according to some embodiments. FIG. 9 depicts a topside plan view representation of the NAND cell construction, according to some embodiments. FIG. 10 depicts a backside plan view representation of the NAND cell construction, according to some embodiments. FIG. 11 depicts a cross-sectional representation of the NAND cell construction, according to some embodiments, along line 11-11 shown in FIG. 9 (e.g., along gate bridge 3450′). FIG. 12 depicts a cross-sectional representation of the NAND cell construction, according to some embodiments, along line 12-12 shown in FIG. 9 (e.g., perpendicular to the gate fins of transistor 3410 and transistor 3410′).

NAND cell device 4100 may be derived from the structure of device 3400, shown in FIG. 1. In the illustrated embodiment of FIGS. 8-12, device 4100 includes vertical transistor 3410, vertical transistor 3420, vertical transistor 3410′, and vertical transistor 3420′. Transistor 3410 includes lower source/drain region 3412, gate 3414, and upper source/drain region 3416. Transistor 3420 includes lower source/drain region 3422, gate 3424, and upper source/drain region 3426. Transistor 3410′ includes lower source/drain region 3412′, gate 3414′, and upper source/drain region 3416′. Transistor 3420′ includes lower source/drain region 3422′, gate 3424′, and upper source/drain region 3426′. In the illustrated embodiment of device 4100, transistor 3410 and transistor 3410′ are PMOS transistors and transistor 3420 and transistor 3420′ are NMOS transistors.

In certain embodiments, route for input signals to transistor 3410, transistor 3410′, transistor 3420, and transistor 3420′ are provided by route 3430C. As shown in FIGS. 8 and 9, route 3430C is coupled to gate via 3630A, which is coupled to gate bridge 3450, and gate via 3630B, which is coupled to gate bridge 3450′. Thus, gate via 3630A provides connection between route 3430C (e.g., the input signal route) and both gate 3414 in transistor 3410 and gate 3424 in transistor 3420. Gate via 3630B provides connection between route 3430C (e.g., the input signal route) and both gate 3414′ in transistor 3410′ and gate 3424′ in transistor 3420′.

In certain embodiments, upper source/drain region 3416 of transistor 3410 and upper source/drain region 3416′ of transistor 3410′ are connected by contact 3418. Similarly, upper source/drain region 3426 of transistor 3420 and upper source/drain region 3426′ of transistor 3420′ are connected by contact 3428. In various embodiments, device 4100 includes topside via 3620 connected to contact 3418. Topside via 3620 may provide connection to route 3430B in the first metal layer above the transistor region of device 4100. In the illustrated embodiment, route 3430B provides a route for output signals from transistor 3410 and transistor 3410′.

In the illustrated embodiment, only transistor 3410, transistor 3410′, and transistor 3420 are connected to backside layers. For instance, transistor 3410 is connected to backside power routing 3440A by contact 3419 and backside via 3610A, transistor 3410′ is connected to backside power routing 3440A by contact 3419′ and backside via 3610A′, and transistor 3420 is connected to backside power routing 3440B by contact 3429 and backside via 3610B, as shown in FIGS. 7 and 10. In various embodiments of device 4100, backside power routing 3440A provides power supply (e.g., Vdd) to lower source/drain region 3412 and transistor 3410 and to lower source/drain region 3412′ and transistor 3410′ while backside power routing 3440B provides ground supply (e.g., Vss) to lower source/drain region 3422 and transistor 3420.

In certain embodiments, lower source/drain region 3422′ in transistor 3420′ is connected to contact 3429′, which is not connected to a backside power routing layer. Contact 3429′ extends away from lower source drain region 3422′ and towards a boundary of the cell, as shown in FIGS. 8, 10, and 11. Contact 3429′ is then coupled to route 3430E by contact via 4110. Route 3430E is a route in the first metal layer above the transistor region. Contact via 4110 is a via that belongs to the cell structure of device 4100 and is not shared with any neighboring cells along the cell boundary. In certain embodiments, route 3430E is a signal route in the first metal layer for signal output from transistor 3420′. Thus, a signal in the NMOS transistors (e.g., transistor 3420 and transistor 3420′) routes from lower source/drain region 3422 (connected to ground by backside power routing 3440B), through the transistors, and out through contact via 4110 to route 3430E.

In the illustrated embodiment, route 3430E provides a route for output signals from transistor 3420 and transistor 3420′. The output signals routed through route 3430E may be combined with output signals from route 3430B. For example, a metal layer above the first metal layer may include a strap (or other connector) coupling route 3430B and route 3430E such that the outputs of the transistors are merged together into a single output.

The various routings and connections in device 4100 form the NAND cell device. FIGS. 9 and 10 illustrate gate fins 3415, 3415′, 3425, 3425′ in gates 3414, 3414′, 3424, 3424′, respectively. Gate fins 3415′ and gate fin 3425′ are also shown in the cross-sectional representation of device 4100 in FIG. 11 and gate fin 3415 and gate fin 3415′ are shown in the cross-sectional representation of device 4100 in FIG. 12. Note that the cross-section representation of FIG. 12 is perpendicular to the gate fins of transistor 3410 and transistor 3410′, which is the direction of route 3430B, shown in FIG. 9.

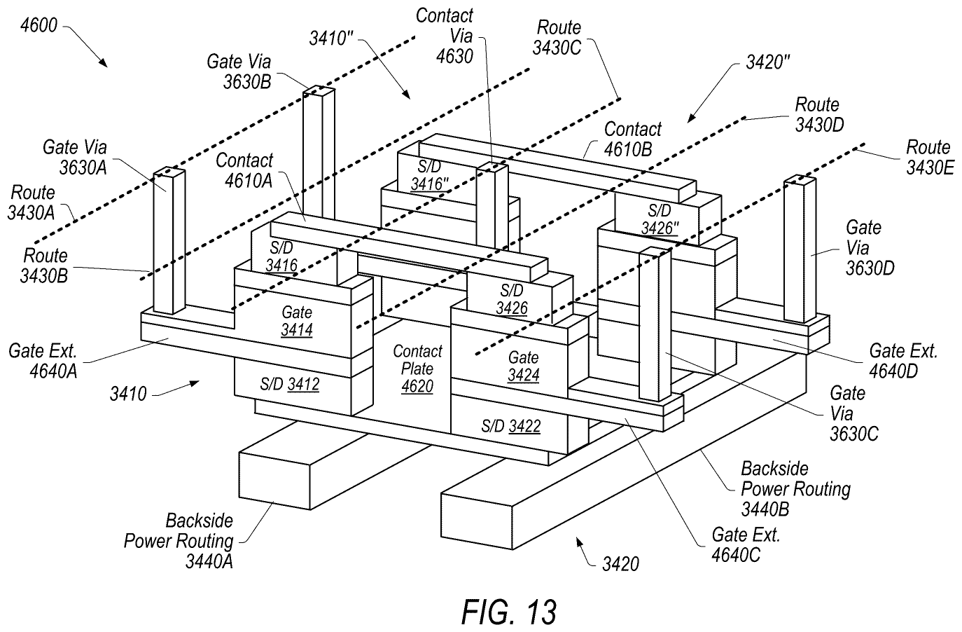

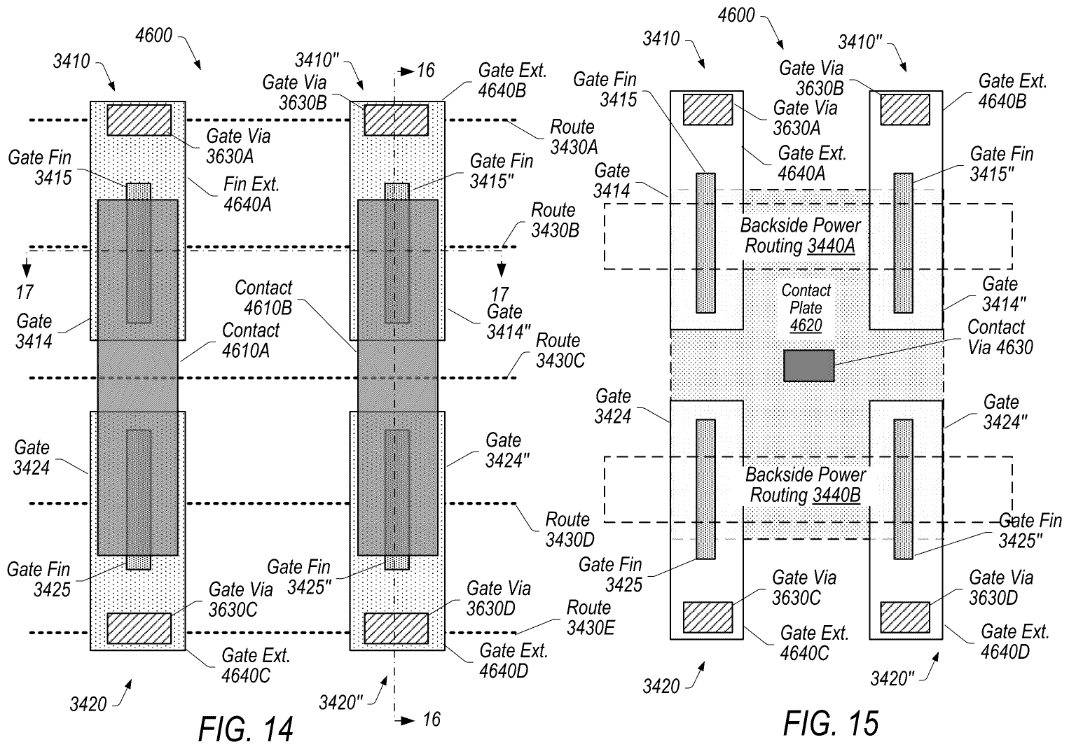

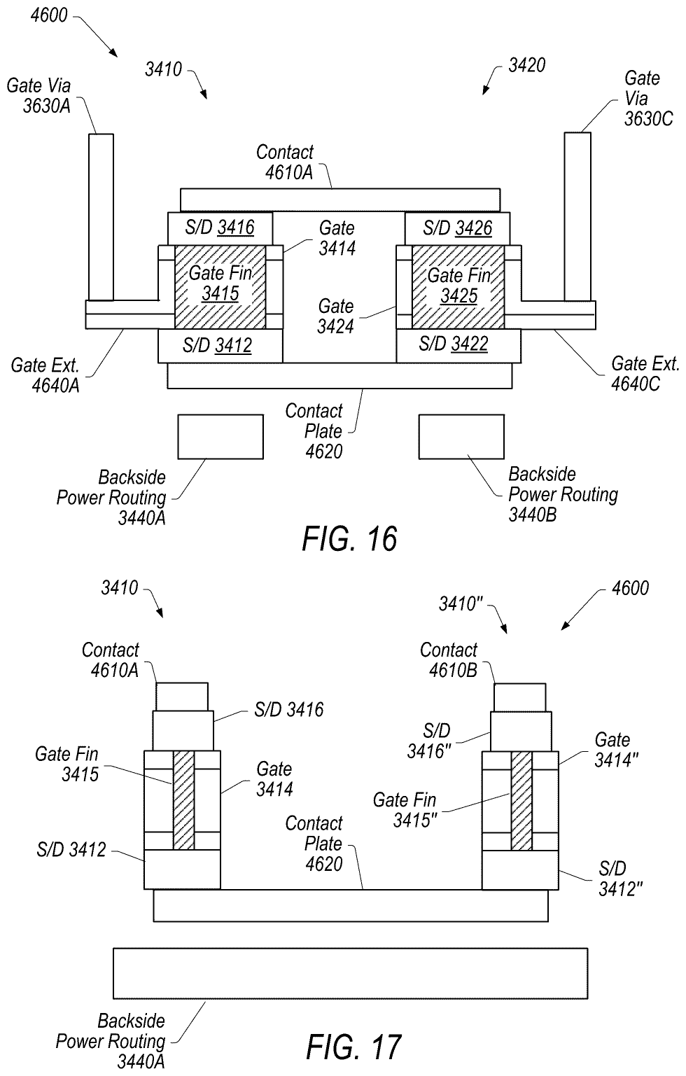

FIGS. 13-17 depict representations of a MUX (multiplexer) cell construction, according to some embodiments. FIG. 13 depicts a perspective view representation of the MUX cell construction, according to some embodiments. FIG. 14 depicts a topside plan view representation of the MUX cell construction, according to some embodiments. FIG. 15 depicts a backside plan view representation of the MUX cell construction, according to some embodiments. FIG. 16 depicts a cross-sectional representation of the MUX cell construction, according to some embodiments, along line 16-16 shown in FIG. 14 (e.g., along gate fin 3415′ and gate fin 3425″). FIG. 17 depicts a cross-sectional representation of the MUX cell construction, according to some embodiments, along line 17-17 shown in FIG. 14 (e.g., perpendicular to the gate fins of transistor 3410 and transistor 3410″).

MUX cell device 4600 may be derived from the structure of device 3500, shown in FIG. 2. In the illustrated embodiment of FIGS. 13-17, device 4600 includes vertical transistor 3410, vertical transistor 3420, vertical transistor 3410″, and vertical transistor 3420″. As in device 3500, there are no gate bridges between gates of the transistors in device 4600 so that there are no common gates between complementary type transistors. Transistor 3410 includes lower source/drain region 3412, gate 3414, and upper source/drain region 3416. Transistor 3420 includes lower source/drain region 3422, gate 3424, and upper source/drain region 3426. Transistor 3410″ includes lower source/drain region 3412″, gate 3414″, and upper source/drain region 3416″. Transistor 3420″ includes lower source/drain region 3422″, gate 3424″, and upper source/drain region 3426″. In the illustrated embodiment of device 4600, transistor 3410 and transistor 3410″ are PMOS transistors and transistor 3420 and transistor 3420″ are NMOS transistors.

As MUX cell device 4600 is a transmission device, none of transistor 3410 and transistor 3410″ and none of transistor 3420 and transistor 3420″ are connected to any power in the MUX cell structure. In various embodiments of MUX cell device 4600, the lower source/drain regions of the transistors are connected together (e.g., merged together). For instance, in the illustrated embodiment, contact plate 4620 is connected to lower source/drain region 3412 in transistor 3410, lower source/drain region 3412″ in transistor 3410″, lower source/drain region 3422 in transistor 3420, and lower source/drain region 3422″ in transistor 3420″.

In certain embodiments, contact via 4630 is coupled to contact plate 4620. Contact via 4630 may be connected to contact plate 4620 at or near a center of the contact plate. Contact via 4630 then connects to route 3430C in the first metal layer above the transistor region. In various embodiments, route 3430C provides output routing for MUX cell device 4600. Thus, contact via 4630 may be referred to as an output pin of MUX cell device 4600.

In various embodiments, gates 3414, 3414″, 3424, 3424″ are extended towards the boundary of the cell to provide surfaces for direct vertical connections to the gates from routes in the first metal layer above. For example, as illustrated in FIGS. 13-17, gate 3414 includes gate extension 4640A that extends toward the boundary of the cell (e.g., extends horizontally towards the boundary of the cell). Similarly, gate 3414″ includes gate extension 4640B, gate 3424 includes gate extension 4640C, and gate 3424″ includes gate extension 4640D. The gate extensions 4640A-D are then connected to routes in the first metal layer above by gate vias 3630A-D, respectively. For example, as shown in FIGS. 13 and 14, gate via 3630A connects gate extension 4640A to route 3430A, gate via 3630B connects gate extension 4640B to route 3430A, gate via 3630C connects gate extension 4640C to route 3430E, and gate via 3630D connects gate extension 4640D to route 3430E. One or both of route 3430A and route 3430E are located at the boundary of the cell and are not shared with neighboring cells. Route 3430A and route 3430E may provide input routes to device 4600.

In certain embodiments, upper source/drain region 3416 in transistor 3410 is connected to upper source/drain region 3426 in transistor 3420 by contact 4610A. This connection merges upper source/drain region 3416 with upper source/drain region 3426. Similarly, upper source/drain region 3416″ in transistor 3410″ is connected to upper source/drain region 3426″ in transistor 3420″ by contact 4610B. With the merging of these upper source/drain regions and the common connection between the lower source/drain regions (and single output through contact via 4630), device 4600 may operate as a MUX (multiplexer) where signals are input through gate vias 3630A-D and output through contact via 4630.

FIGS. 14 and 15 illustrate gate fins 3415, 3415″, 3425, 3425″ in gates 3414, 3414″, 3424, 3424″, respectively. Gate fins 3415 and gate fin 3425 are also shown in the cross-sectional representation of device 4600 in FIG. 16 and gate fin 3415 and gate fin 3415″ are shown in the cross-sectional representation of device 4600 in FIG. 17. Note that the cross-section representation of FIG. 17 is perpendicular to the gate fins of transistor 3410 and transistor 3410″, which is the direction of route 3430B, shown in FIG. 14.

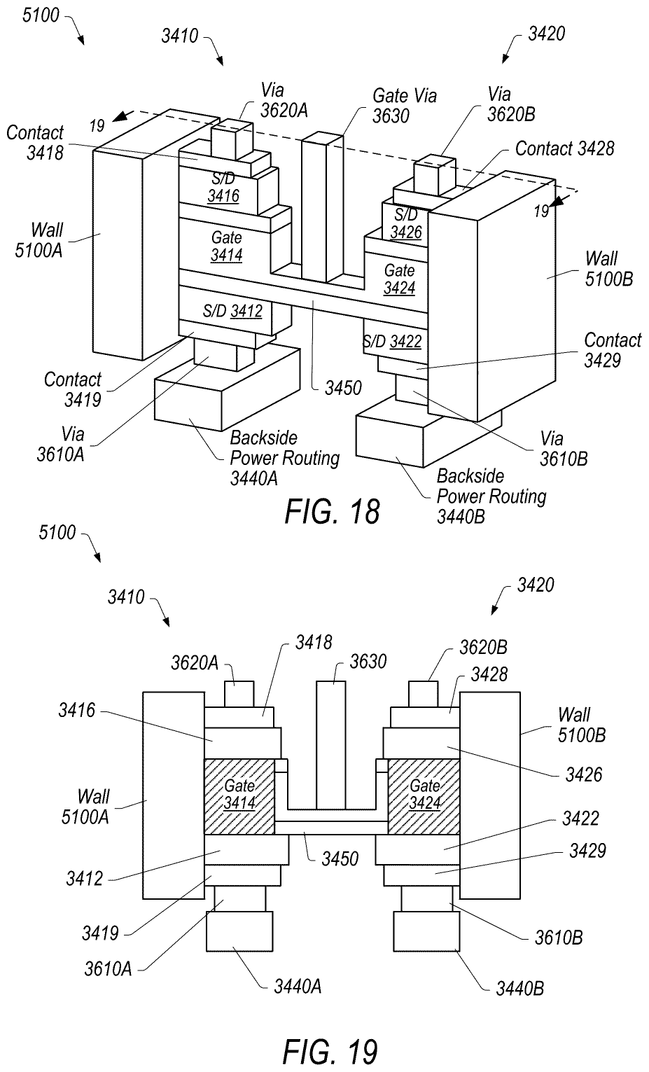

FIGS. 18 and 19 depict representations of a cell device having dielectric walls, according to some embodiments. FIG. 18 depicts a perspective view representation of device 5100, according to some embodiments. FIG. 19 depicts a cross-sectional representation of device 5100, according to some embodiments, along line 19-19 shown in FIG. 51 (e.g., along gate bridge 3450′).

Device 5100 may be derived from the structure of device 3400, shown in FIG. 1. In some embodiments, device 5100 may be similar to the inverter cell device 4100, shown in FIGS. 8-12. In the illustrated embodiment of FIGS. 18 and 19, device 5100 includes vertical transistor 3410 and vertical transistor 3420. Transistor 3410 includes lower source/drain region 3412, gate 3414, and upper source/drain region 3416. Transistor 3420 includes lower source/drain region 3422, gate 3424, and upper source/drain region 3426. In certain embodiments, transistor 3410 is a PMOS transistor and transistor 3420 is an NMOS transistor.

In various embodiments, as shown in FIGS. 18 and 19, wall 5100A may be positioned on one a first side of the cell (e.g., on a side of transistor 3410) and wall 5100B may be positioned on a second side of the cell (e.g., on a side of transistor 3420 opposite transistor 3410). In certain embodiments, wall 5100A and wall 5100B are dielectric walls. Placing dielectric walls on one or both sides of device 5100 may reduce the space needed between device 5100 and another neighboring cell. Accordingly, wall 5100A and wall 5100B may be implemented when reducing in scaling of devices is necessary.

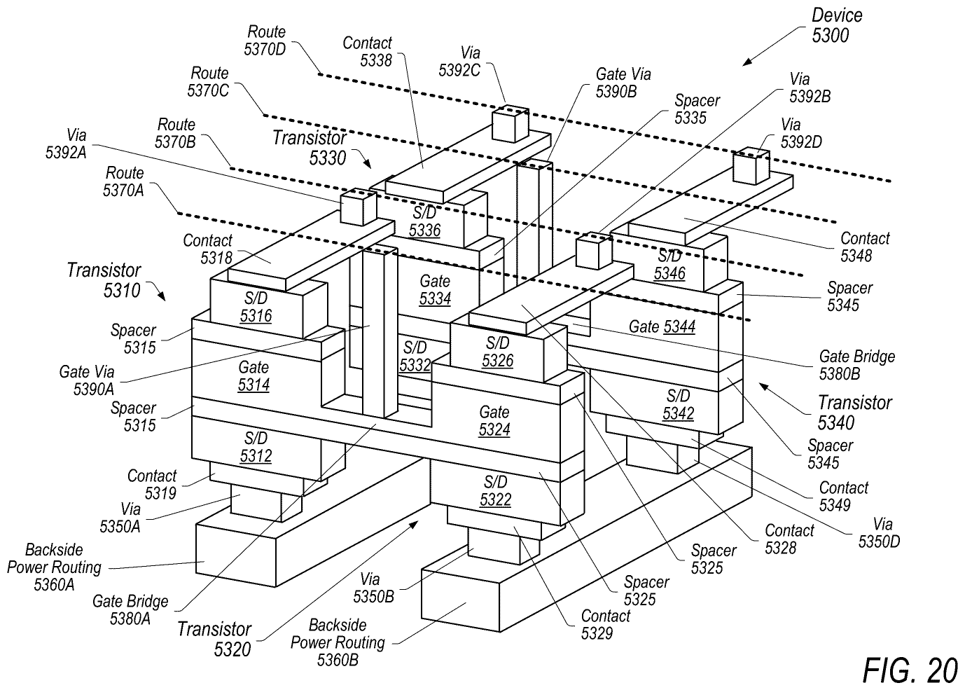

FIGS. 20-33 depict various example device cell constructions for integrated circuit cell devices with vertical transistors. In these example device cell constructions, the devices have a first metal layer in a cell height direction (e.g., along the cell height direction) that is utilized for signal input/output connections to the vertical transistors. It should be noted that the various device cell constructions are provided as example and that various additional device cell constructions may be implemented based on the description herein. For instance, the depicted device cell constructions include an inverter cell construction, a NAND cell construction, and a MUX (multiplexer) cell construction. These cell constructions may provide base cell construction that may be implemented in various types of integrated circuit devices.

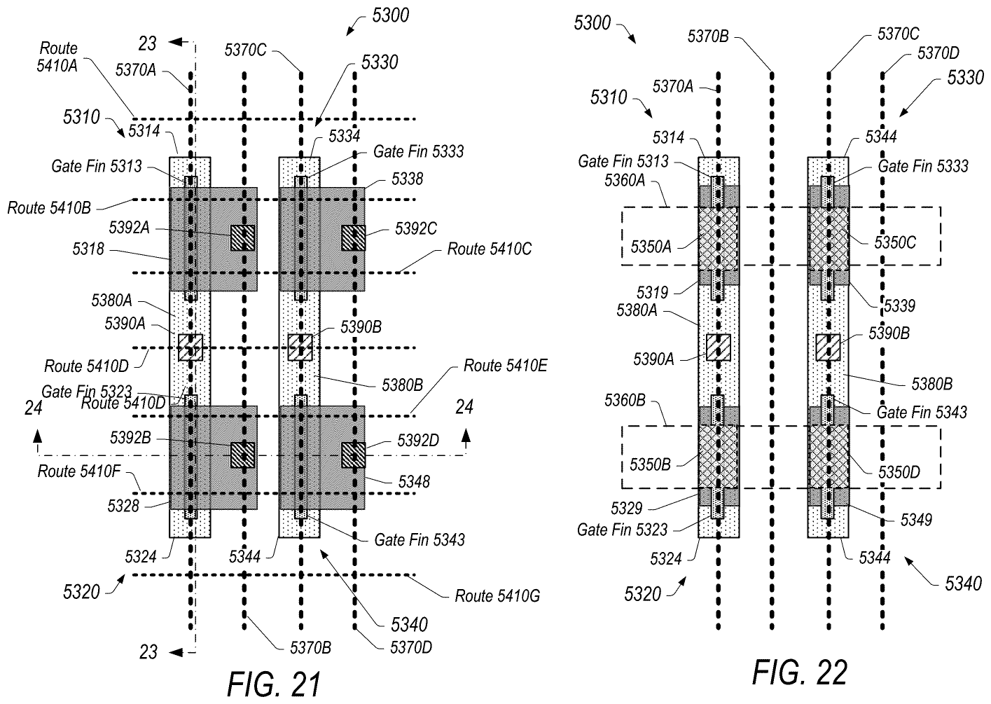

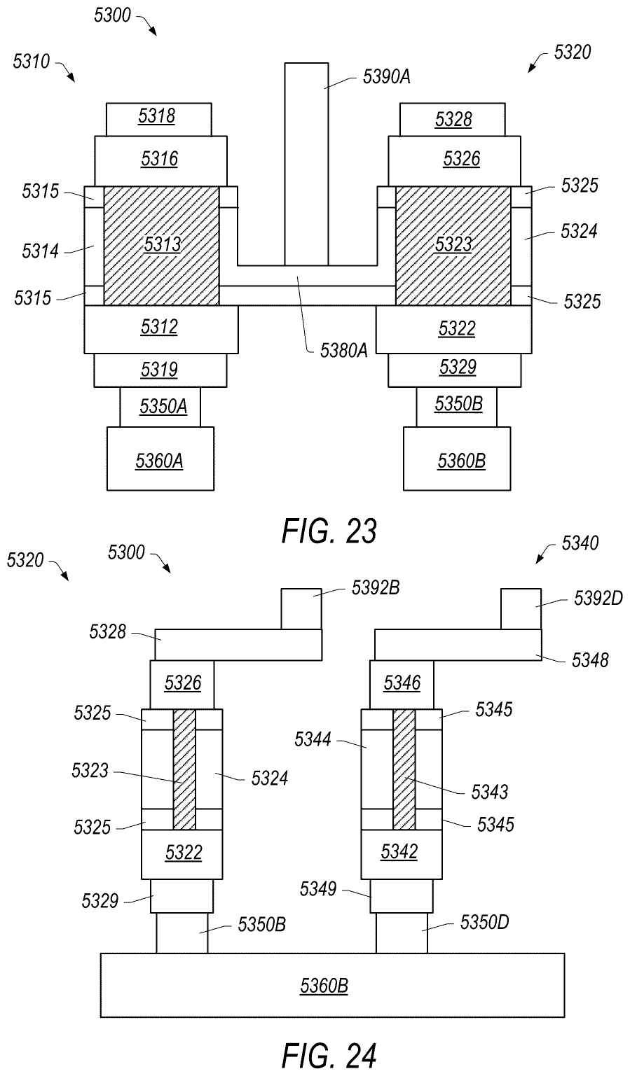

FIGS. 20-24 depict representations of an inverter cell construction, according to some embodiments. FIG. 20 depicts a perspective view representation of the inverter cell construction, according to some embodiments. FIG. 21 depicts a topside plan view representation of the inverter cell construction, according to some embodiments. FIG. 22 depicts a backside plan view representation of the inverter cell construction, according to some embodiments. FIG. 23 depicts a cross-sectional representation of the inverter cell construction, according to some embodiments, along line 23-23 shown in FIG. 21 (e.g., along a gate bridge in the cell height direction). FIG. 24 depicts a cross-sectional representation of the inverter cell construction, according to some embodiments, along line 24-24 shown in FIG. 21 (e.g., perpendicular to the gate bridge in the gate pitch direction).

Inverter cell device 5300 may be derived from the structure of device 3400, shown in FIG. 1, and device 3600, shown in FIG. 3. In the illustrated embodiment of FIGS. 20-24, device 5300 includes four vertical transistors 5310, 5320, 5330, and 5340. Transistor 5310 includes lower source/drain region 5312, gate 5314, gate spacers 5315, upper source/drain region 5316. Transistor 5320 includes lower source/drain region 5322, gate 5324, gate spacers 5325, upper source/drain region 5326, upper contact 5328, and lower contact 5329. Similarly, transistor 5330 includes lower source/drain region 5332, gate 5334, gate spacers 5335, upper source/drain region 5336, upper contact 5338, and lower contact 5339; and transistor 5340 includes lower source/drain region 5342, gate 5344, gate spacers 5345, upper source/drain region 5346, upper contact 5348, and lower contact 5349. In the illustrated embodiment of device 5300, transistors 5310 and 5330 are PMOS transistors and transistors 5320 and 5340 are NMOS transistors. Note that some components may be hidden in some views in FIGS. 20-24.

Device 5300 may include various contacts to the transistors (e.g., transistors 5310, 5320, 5330, 5340) for signal or power routing. For example, device 5300 may include upper contact 5318 connected to upper source/drain region 5316 and lower contact 5319 connected to lower source/drain region 5312 for transistor 5310; upper contact 5328 connected to upper source/drain region 5326 and lower contact 5329 connected to lower source/drain region 5322 for transistor 5320; upper contact 5338 connected to upper source/drain region 5336 and lower contact 5339 connected to lower source/drain region 5332 for transistor 5330; and upper contact 5348 connected to upper source/drain region 5346 and lower contact 5349 connected to lower source/drain region 5342 for transistor 5340. In various embodiments, device 5300 includes backside vias 5350A, 5350B, 5350C, 5350D to transistors 5310, 5320, 5330, 5340. Backside via 5350A is coupled to lower source/drain region 5312 through lower contact 5319. Backside via 5350B is coupled to lower source/drain region 5322 through lower contact 5329. Backside via 5350C is coupled to lower source/drain region 5332 through lower contact 5339. Backside via 5350D is coupled to lower source/drain region 5342 through lower contact 5349.

In the illustrated embodiment, backside vias 5350A, 5350C couple lower source/drain regions 5312, 5332 of transistors 5310, 5330, respectively, to backside power routing 5360A. Backside vias 5350B, 5350D couple lower source/drain regions 5322, 5342 of transistors 5320, 5340 to backside power routing 5360B. For device 5300, backside power routing 5360A provides power supply (e.g., Vdd) to lower source/drain regions 5312, 5332 and transistors 5310, 5330 while backside power routing 5360B provides ground supply (e.g., Vss) to lower source/drain regions 5322, 5342 and transistors 5320, 5340. Backside power routing 5360A and backside power routing 5360B though can be switched with backside power routing 5360B providing power supply and backside power routing 5360A providing ground supply.

The topside and backside plan views of device 5300 shown in FIGS. 21 and 22, respectively, further depict gate fins that may be present in the gates of the transistors. For example, gate fin 5313 is the gate fin for gate 5314, gate fin 5323 is the gate fin for gate 5324, gate fin 5333 is the gate fin for gate 5334, and gate fin 5343 is the gate fin for gate 5345. Gate fins 5313 and gate fin 5323 are shown in the cross-sectional representation of device 5300 in FIG. 23 and gate fin 5323 and gate fin 5343 are shown in the cross-sectional representation of device 5300 in FIG. 24.

In various embodiments, gate pairs (e.g., a gate pair of gate 5314 and gate 5324 or a gate pair of gate 5334 and gate 5344) are interconnected by a gate bridge. For instance, in the illustrated embodiment, gate 5314 and gate 5324 are interconnected by gate bridge 5380A and gate 5334 and gate 5344 are interconnected by gate bridge 5380B. Gate bridges 5380A, 5380B may be formed, for example, by extension of gate material across the space between the gates, as depicted in FIGS. 20-23. Gate bridge 5380A merges gate 5314 and gate 5324 while gate bridge 5380B merges gate 5334 and gate 5344 for implementation of transistors 5310, 5320, 5330, 5340 in an inverter device. In some embodiments, gate bridges 5380A, 5380B may also include extensions of material for gate spacers between the transistors. For instance, gate bridge 5380A includes extension of material for gate spacers 5315 and 5325 and gate bridge 5380B includes extension of material for gate spacers 5335 and 5345.

In certain embodiments, gate vias 5390A, 5390B are connected to gate bridges 5380A, 5380B, respectively. Gate vias 5390A, 5390B may be vias utilized to connect gate bridges 5380A, 5380B with routing in the first metal layer, as described below. Connecting gate via 5390A to gate bridge 5380A allows a single signal input connections to be implemented for connecting to the pairs of gate 5314 and gate 5324, which are merged by the bridge. Similarly, a single signal input for gates 5334 and 5344 is provided by gave via 5390B connected to gate bridge 5380B.

In various embodiments, device 5300 includes topside vias 5392A, 5392B, 5392C, 5392D. Topside vias 5392A, 5392B, 5392C, 5392D may be coupled to upper source/drain regions 5316, 5326, 5336, 5346 through upper contacts 5318, 5328, 5338, 5348, respectively. As shown in the illustrated embodiment, upper contacts 5318, 5328, 5338, 5348 may include portions that extend from where the upper contacts connect to upper source/drain regions 5316, 5326, 5336, 5346 to where the upper contacts connect to topside vias 5392A, 5392B, 5392C, 5392D. Thus, upper contacts 5318, 5328, 5338, 5348 redistribute horizontal positions for connections to upper source/drain regions 5316, 5326, 5336, 5346 from the horizontal positions of the upper source/drain regions to the horizontal positions of topside vias 5392A, 5392B, 5392C, 5392D. Topside vias 5392A, 5392B, 5392C, 5392D may provide connection to signal routing resources (e.g., routes 5370B, D) in a first topside metal layer above the transistors in device 5300, as described below.

In certain embodiments, device 5300 includes a first topside metal layer with signal routing having routes that run in a cell height direction (e.g., along vertical direction of the integrated circuit cell, as shown in FIGS. 21 and 22). In the illustrated embodiment, the signal routing of the first topside metal layer includes four signal routes 5370A, 5370B, 5370C, 5370D (represented by dashed lines) that run in the cell height direction. As these signal routes 5370A-D run in the cell height direction, the signal routes may have a pitch (e.g., a metal pitch) that has a 1:2 ratio relative to the gate pitch (e.g., contact poly pitch) in device 5300.

With the pitch of signal routes 5370A-D being narrower compared to the pitch of gates 5314, 5324, 5334, 5344, the signal routes may be used for both input and output signal routing to transistors 5310, 5320, 5330, 5340. For instance, in the illustrated embodiment, signal route 5370A and signal route 5370C are input signal routes that are connected to gate via 5390A and gate via 5390B, respectively. Thus, signal route 5370A provides input signals to merged transistors 5310 and 5320 (e.g., the transistors with gate 5314 and gate 5324 merged by gate bridge 5380A and coupled to gate via 5390A). Similarly, signal route 5370C provides input signals to merged transistors 5330 and 5340 (e.g., the transistors with gate 5334 and gate 5344 merged by gate bridge 5380B and coupled to gate via 5390B).

Further in the illustrated embodiment, signal route 5370B and signal route 5370D are output signal routes. Signal route 5370B is connected to the outputs of transistors 5310 and 5320 through upper source/drain regions 5316, 5326, upper contacts 5318, 5328, and topside vias 5392A, 5392B. Signal route 5370D is connected to the outputs of transistors 5330 and 5340 through upper source/drain regions 5336, 5346, upper contacts 5338, 5348, and topside vias 5392C, 5392D. In device 5300, both input and output signal routes are allowed to be in the same topside metal layer due to the metal pitch being ½ the gate pitch in the device. This difference in pitch allows signal routes 5370A, 5370C to be above the gates (e.g., above the gate fins) and signal routes 5370B, 5370D to be in between the gates (e.g., in between the gate fins). Accordingly, the metal pitch described above allows device 5300 to have connected gate logic through a single topside metal layer for an inverter device with four vertical transistors.

It should be noted that while FIGS. 20-22 (and additional figures herein) depict four routes 5370A-D in the first topside metal layer above transistors 5310, 5320, 5330, 5340, the first topside metal layer may include additional routes. Further, additional metal layers may be positioned above the first topside metal layer and provide various connections to either the first topside metal layer or device 5300. For example, in one embodiment, another topside metal layer above the first topside metal layer may include a strap (or other connector) coupling route 5370B and route 5370D such that the outputs of the transistors are merged together into a single output. Examples of routing in a second topside metal layer are shown in FIG. 21 by routes 5410A-G. Note that the routing in the second topside metal layer is perpendicular to the routing in the first topside metal layer. Additionally, while two backside power routings are shown (e.g., routing 5360A and routing 5360B), the backside power layer may include additional routings (e.g., routings for other power resources).

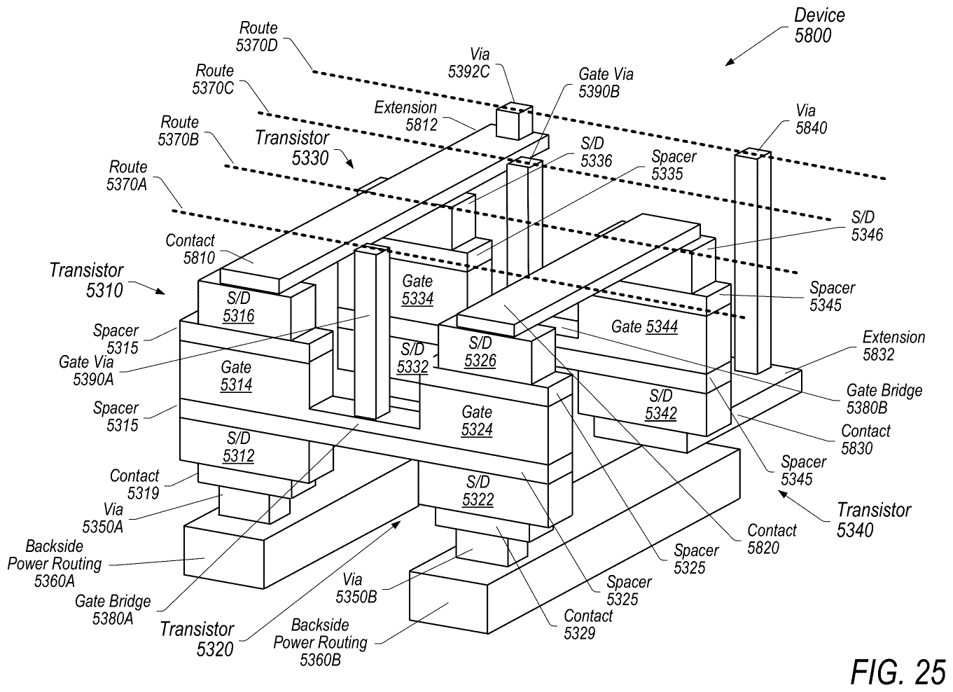

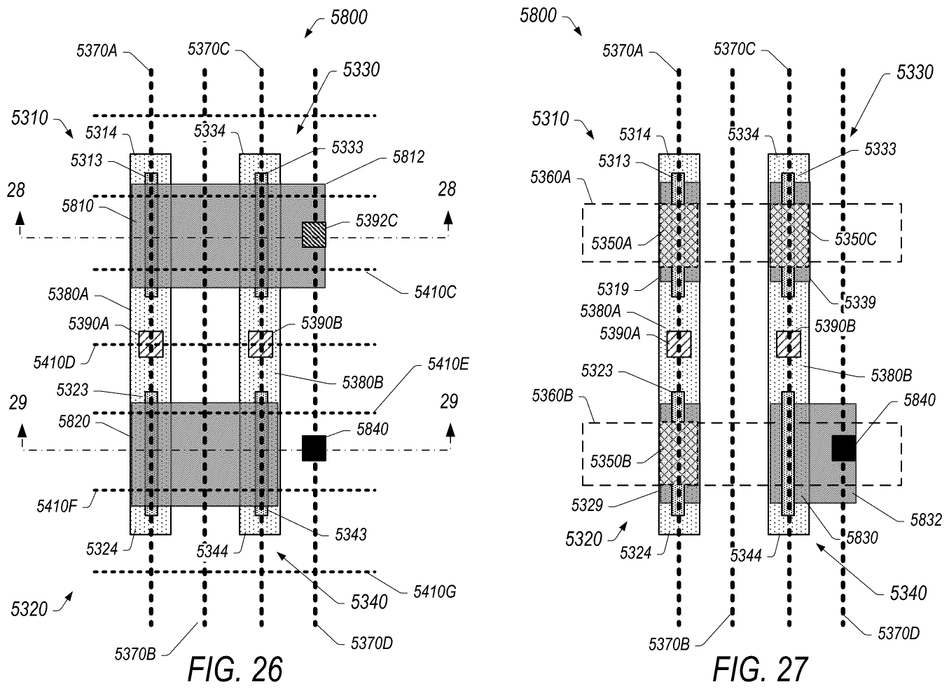

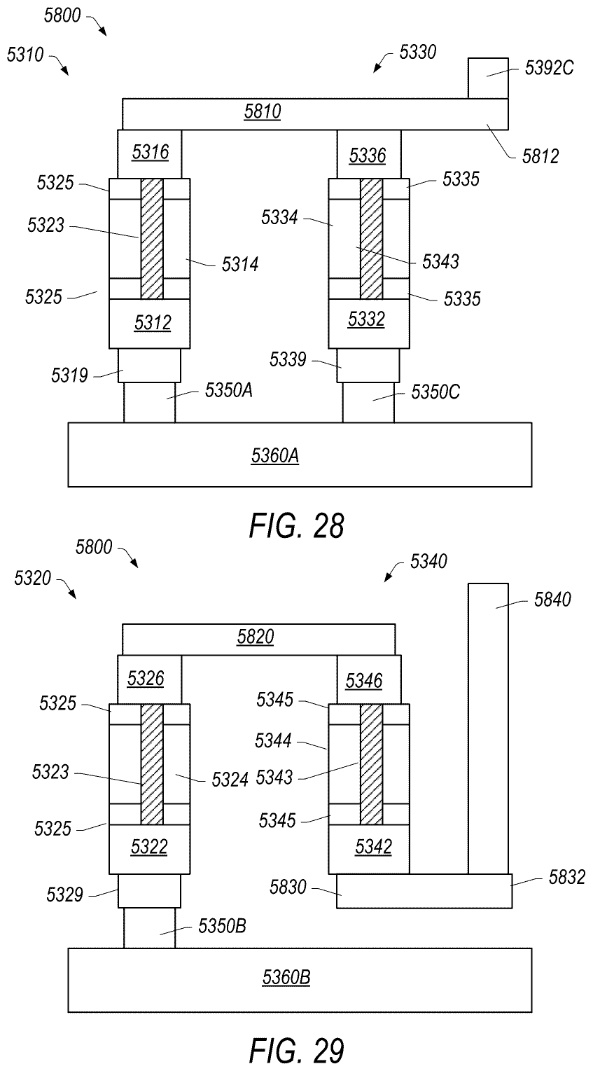

FIGS. 25-29 depict representations of a NAND cell construction, according to some embodiments. FIG. 25 depicts a perspective view representation of the NAND cell construction, according to some embodiments. FIG. 26 depicts a topside plan view representation of the NAND cell construction, according to some embodiments. FIG. 27 depicts a backside plan view representation of the NAND cell construction, according to some embodiments. FIG. 28 depicts a cross-sectional representation of the NAND cell construction, according to some embodiments, along line 28-28 shown in FIG. 26 (e.g., across gate fin 5313 and gate fin 5333). FIG. 29 depicts a cross-sectional representation of the NAND cell construction, according to some embodiments, along line 29-29 shown in FIG. 26 (e.g., across gate fin 5323 and gate fin 5343).

NAND cell device 5800 may be derived from the structure of device 3400, shown in FIG. 1, and device 4100, shown in FIG. 8. In the illustrated embodiment of FIGS. 25-29, NAND cell device 5800 includes vertical transistor 5310, vertical transistor 5320, vertical transistor 5330, and vertical transistor 5340. Transistors 5310, 5320, 5330, 5340 are similar to the corresponding transistors shown in FIGS. 20-24. For instance, transistor 5310 includes lower source/drain region 5312, gate 5314, gate spacers 5315, and upper source/drain region 5316; transistor 5320 includes lower source/drain region 5322, gate 5324, gate spacers 5325, and upper source/drain region 5326; transistor 5330 includes lower source/drain region 5332, gate 5334, gate spacers 5335, and upper source/drain region 5336; and transistor 5340 includes lower source/drain region 5342, gate 5344, gate spacers 5345, upper source/drain region 5346. In the illustrated embodiment of device 5800, transistors 5310 and 5330 are PMOS transistors and transistors 5320 and 5340 are NMOS transistors. Note that some components may be hidden in some views in FIGS. 25-29.

Device 5800 may include various contacts to the transistors (e.g., transistors 5310, 5320, 5330, 5340) for signal or power routing. For example, device 5800 may include upper contact 5810 that is connected to both upper source/drain region 5316 of transistor 5310 and upper source/drain region 5336 of transistor 5330. Upper contact 5810 also includes extension portion 5812 that extends (e.g., extends horizontally) towards a boundary of the cell beyond upper source/drain region 5336 of transistor 5330. Topside via 5392C then provides connection between upper contact 5810 and route 5370D. Device 5800 further includes upper contact 5820 that is connected to both upper source/drain region 5326 of transistor 5320 and upper source/drain region 5346 of transistor 5340. Note that there is no extension portion of upper contact 5820.

Device 5800 includes lower contacts to power for transistors 5310, 5320, 5330 but no power contact for transistor 5340, as shown in FIG. 25. Accordingly, device 5800 includes lower contact 5319 connected to lower source/drain region 5312 for transistor 5310; lower contact 5329 connected to lower source/drain region 5322 for transistor 5320; and lower contact 5339 connected to lower source/drain region 5332 for transistor 5330. For power connections, device 5800 includes backside vias 5350A, 5350B, 5350C to transistors 5310, 5320, 5330. Backside via 5350A is coupled to lower source/drain region 5312 through lower contact 5319; backside via 5350B is coupled to lower source/drain region 5322 through lower contact 5329; and backside via 5350C is coupled to lower source/drain region 5332 through lower contact 5339. In certain embodiments of device 5800, backside power routing 5360A provides power supply (e.g., Vdd) to lower source/drain region 5312 and transistor 5310 and to lower source/drain region 5332 and transistor 5330 while backside power routing 5360B provides ground supply (e.g., Vss) to lower source/drain region 5322 and transistor 5320.

For transistor 5340 in device 5800, lower contact 5830 is coupled to lower source/drain region 5342. Lower contact 5830 includes extension portion 5832 that extends (e.g., extends horizontally) towards a boundary of the cell away from lower source/drain region 5342 of transistor 5340, as shown in FIG. 25. As depicted, there is no connection between transistor 5340 and backside power routing 5360B. For connected gate logic associated with a NAND device, device 5800 includes topside-to-backside via 5840 that connects extension portion 5832 of lower contact 5830 to route 5370D.

In certain embodiments, as shown in FIGS. 25-27, route 5370A provides signal input routing to gate via 5390A and route 5370C provides signal input routing to gate via 5390B. Thus, device 5800 may receive two separate input signals, one for transistors 5310 and 5320, which are merged by gate bridge 5380A, and one for transistors 5330 and 5340, which are merged by gate bridge 5380B. Route 5370B is unused (e.g., not connected to any transistors) for NAND cell device 5800.

Output signal routing for device 5800 is provided by route 5370D. As shown in the illustrated embodiment, route 5370D is connected to upper source/drain regions 5316, 5336 of transistors 5310, 5330, respectively, by upper contact 5810, extension portion 5812, and topside via 5392C. Route 5370D is also connected to lower source/drain region 5342 of transistor 5340 by lower contact 5830, extension portion 5832, and topside-to-backside via 5840. Accordingly, the outputs of the transistors are merged together in route 5370D. Extension portion 5812 and extension portion 5832 and their ensuing connections to route 5370D through topside via 5392C and topside-to-backside via 5840, respectively, are allowed in device 5800 due to the 1:2 ratio between metal pitch and gate pitch, described above.

The connections in device 5800 create a connected gate logic for a NAND cell device with inputs through gate vias 5390A, 5390B and outputs through topside via 5392C and topside-to-backside via 5840. As with device 5300, both input and output signal routes for device 5800 are allowed to be in the same topside metal layer due to the metal pitch being ½ the gate pitch in the device. This difference in pitch allows signal routes 5370A, 5370C to be above the gates (e.g., above the gate fins) and signal routes 5370B, 5370D to be in between the gates (e.g., in between the gate fins). Accordingly, the metal pitch described above allows device 5800 to have connected gate logic through a single topside metal layer for a NAND device with four vertical transistors.

While FIGS. 20-24 depict device 5300 having connected gate logic for an inverter device and FIGS. 25-29 depict device 5800 having connected gate logic for a NAND device, it should be understood that various additional embodiments may be contemplated for other connected gate logic for other devices utilizing the four vertical transistors and the signal routes running in the cell height direction in the first topside metal layer. For instance, various other gate extensions, bridges, vias, etc. may be implemented to provide any of various connected gate logic to the vertical transistors independently or in combination.

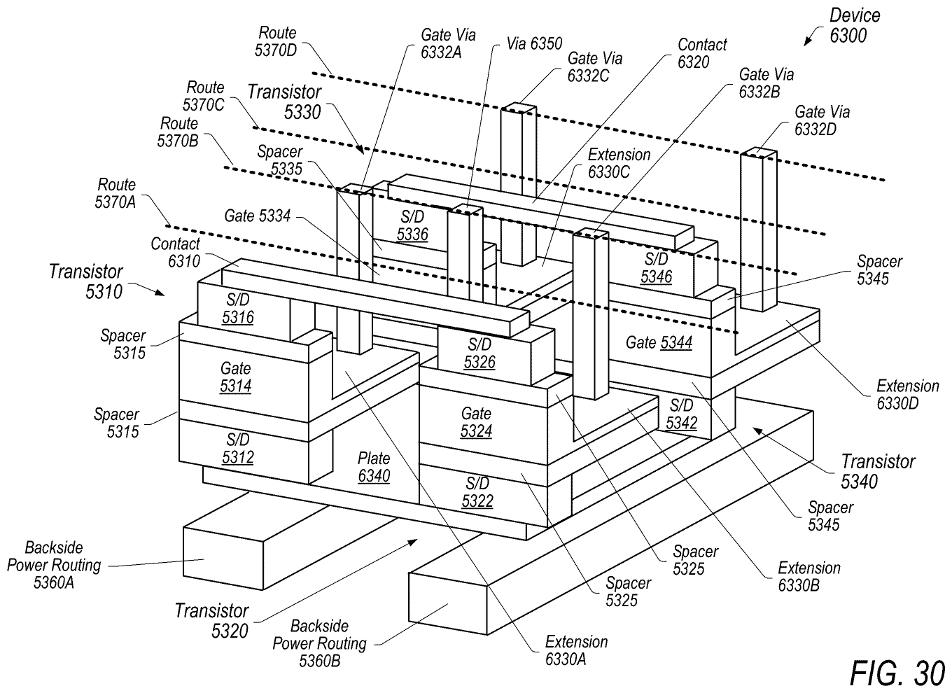

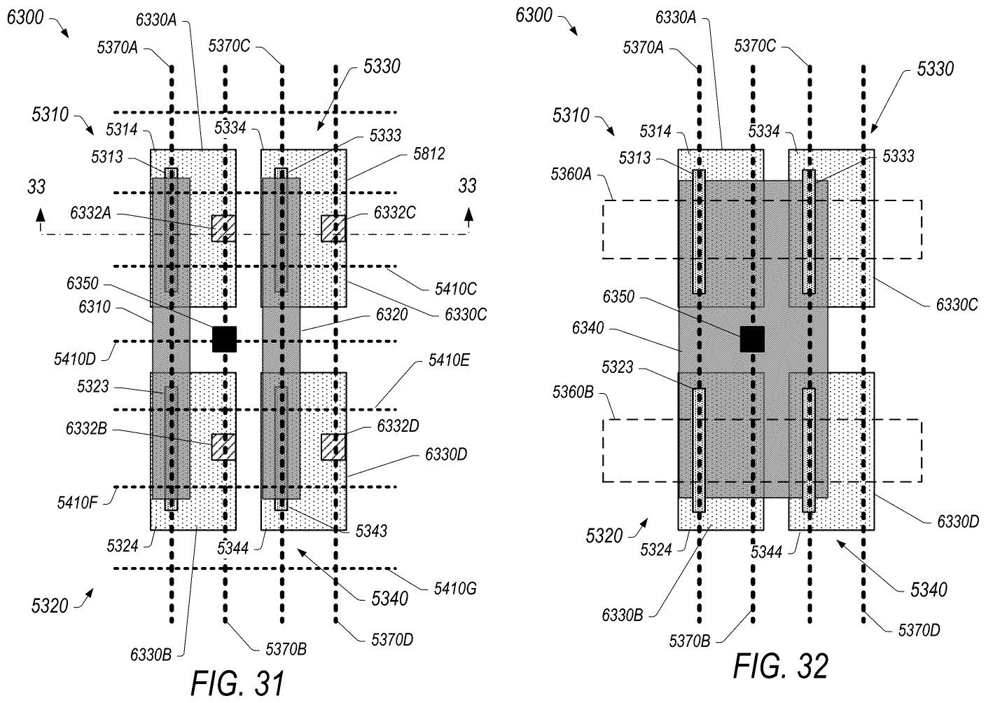

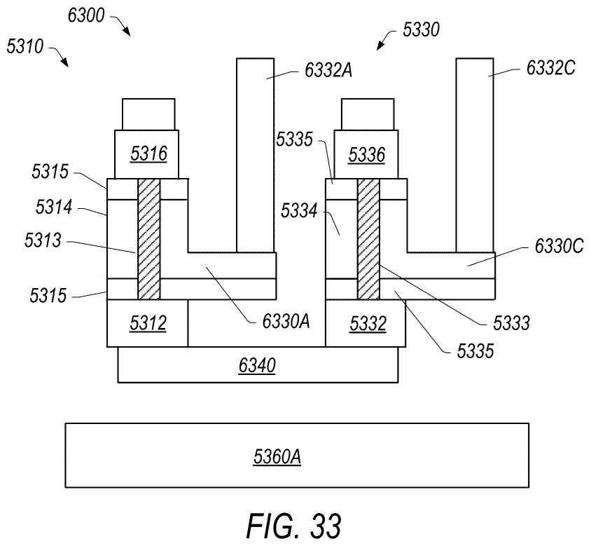

FIGS. 30-33 depict representations of a MUX (multiplexer) cell construction, according to some embodiments. FIG. 30 depicts a perspective view representation of the MUX cell construction, according to some embodiments. FIG. 31 depicts a topside plan view representation of the MUX cell construction, according to some embodiments. FIG. 32 depicts a backside plan view representation of the MUX cell construction, according to some embodiments. FIG. 33 depicts a cross-sectional representation of the MUX cell construction, according to some embodiments, along line 33-33 shown in FIG. 31 (e.g., across gate fin 5313 and gate fin 5333).

MUX cell device 6300 may be derived from the structure of device 3500, shown in FIG. 2, and device 4600, shown in FIG. 13. In the illustrated embodiment of FIGS. 30-33, device 6300 includes vertical transistor 5310, vertical transistor 5320, vertical transistor 5330, and vertical transistor 5340. Transistors 5310, 5320, 5330, 5340 are similar to the corresponding transistors shown in FIGS. 20-24. For instance, transistor 5310 includes lower source/drain region 5312, gate 5314, gate spacers 5315, and upper source/drain region 5316; transistor 5320 includes lower source/drain region 5322, gate 5324, gate spacers 5325, and upper source/drain region 5326; transistor 5330 includes lower source/drain region 5332, gate 5334, gate spacers 5335, and upper source/drain region 5336; and transistor 5340 includes lower source/drain region 5342, gate 5344, gate spacers 5345, upper source/drain region 5346. In the illustrated embodiment of device 5800, transistors 5310 and 5330 are PMOS transistors and transistors 5320 and 5340 are NMOS transistors. Note that some components may be hidden in some views in FIGS. 25-29.

Device 6300 may include various contacts to the transistors (e.g., transistors 5310, 5320, 5330, 5340) for signal routing. For instance, device 6300 includes contact 6310 upper source/drain region 5316 in transistor 5310 is connected to upper source/drain region 5326 in transistor 5320 by upper contact 6310. Thus, upper contact 6310 merges upper source/drain region 5316 with upper source/drain region 5326. Similarly, upper source/drain region 5336 in transistor 5330 is connected to upper source/drain region 5346 in transistor 5340 by contact 6320. Thus, upper contact 6320 merges upper source/drain region 5336 with upper source/drain region 5346.

In various embodiments, gates 5314, 5324, 5334, 5344 are extended to provide surfaces for direct vertical connections to the gates from routes 5370B, 5370D in the first topside metal layer. For example, as illustrated in FIGS. 30-33, gate 5314 includes gate extension 6330A that extends (e.g., extends horizontally) toward gate 5334. Similarly, gate 5324 includes gate extension 6330B that extends (e.g., extends horizontally) toward gate 5344. Connections to route 5370B are then provided by gate via 6332A, connected to gate extension 6330A, and gate via 6332B, connected to gate extension 6330B. Gate extensions 6330A, 6330B and their ensuing connections to route 5370B through gate vias 6332A, 6332B, respectively, are allowed in device 6300 due to the 1:2 ratio between metal pitch and gate pitch, described above. Note that gate extensions 6330A-D may include both gate material and gate spacer material.

The ratio between metal pitch and gate pitch further allows gate extension 6330C from gate 5334 and gate extension 6330D from gate 5344 to extend (e.g., extend horizontally) towards a boundary of the cell without increasing the size of the cell beyond a standard cell size. Gate extension 6330C and gate extension 6330D are connected to route 5370D by gate via 6332C and gate via 6332D, respectively. Route 5370B and route 5370D may provide input signal routes to device 6300 through the connections to the gates of the transistors in the device.

As MUX cell device 6300 is a transmission device, none of transistors 5310, 5320, 5330, 5340 are connected to any power routing (e.g., backside power routing 5360A or backside power routing 5360B) in the MUX cell structure. In various embodiments of MUX cell device 6300, the lower source/drain regions of the transistors (e.g., lower source/drain regions 5312, 5322, 5332, 5342) are connected together to provide a transmission device. For example, in the illustrated embodiment, device 6300 includes contact plate 6340 that is connected to lower source/drain region 5312 in transistor 5310, lower source/drain region 5322 in transistor 5320, lower source/drain region 5332 in transistor 5330, and lower source/drain region 5342 in transistor 5340.

In various embodiments, topside-to-backside via 6350 is coupled to contact plate 6340. In certain embodiments, via 6350 is connected to contact plate 6340 at or near a center of the contact plate. Via 6350 then connects to route 5370B in the first metal layer above the transistors. In various embodiments, route 5370B provides output routing for device 6300. Thus, via 6350 may be referred to as an output pin of device 6300. With the merging of the pairs of upper source/drain regions in device 6300 by upper contact 6310 and upper contact 6320 and the common connection between the lower source/drain regions (and single output through via 6350), device 6300 may operate as a MUX (multiplexer) where signals are input through gate vias 6332A-D and output through via 6350. Accordingly, the topside metal layer routing and metal pitch versus gate pitch described herein allows device 6300 to have disconnected gate logic through a single topside metal layer for a MUX device with four vertical transistors.

While FIGS. 30-33 depict device 6300 having disconnected gate logic for a MUX device, it should be understood that various additional embodiments may be contemplated for other disconnected gate logic for other devices utilizing the four vertical transistors and the signal routes running in the cell height direction in the first topside metal layer. For instance, various other gate extensions, bridges, vias, etc. may be implemented to provide any of various disconnected gate logic to the vertical transistors independently or in combination.

### EXAMPLE COMPUTER SYSTEM

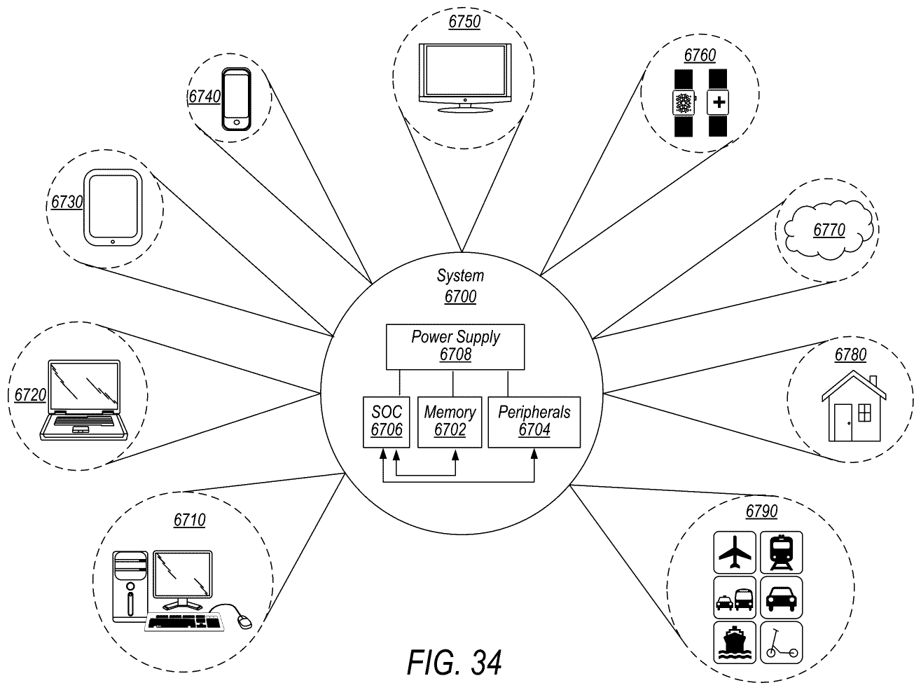

Turning next to FIG. 34, a block diagram of one embodiment of a system 6700 is shown that may incorporate and/or otherwise utilize the methods and mechanisms described herein. In the illustrated embodiment, the system 6700 includes at least one instance of a system on chip (SoC) 6706 which may include multiple types of processing units, such as a central processing unit (CPU), a graphics processing unit (GPU), or otherwise, a communication fabric, and interfaces to memories and input/output devices. In some embodiments, one or more processors in SoC 6706 includes multiple execution lanes and an instruction issue queue. In various embodiments, SoC 6706 is coupled to external memory 6702, peripherals 6704, and power supply 6708.

A power supply 6708 is also provided which supplies the supply voltages to SoC 6706 as well as one or more supply voltages to the memory 6702 and/or the peripherals 6704. In various embodiments, power supply 6708 represents a battery (e.g., a rechargeable battery in a smart phone, laptop or tablet computer, or other device). In some embodiments, more than one instance of SoC 6706 is included (and more than one external memory 6702 is included as well).

The memory 6702 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 6704 include any desired circuitry, depending on the type of system 6700. For example, in one embodiment, peripherals 6704 includes devices for various types of wireless communication, such as Wi-Fi, Bluetooth, cellular, global positioning system, etc. In some embodiments, the peripherals 6704 also include additional storage, including RAM storage, solid state storage, or disk storage. The peripherals 6704 include user interface devices such as a display screen, including touch display screens or multitouch display screens, keyboard or other input devices, microphones, speakers, etc.

As illustrated, system 6700 is shown to have application in a wide range of areas. For example, system 6700 may be utilized as part of the chips, circuitry, components, etc., of a desktop computer 6710, laptop computer 6720, tablet computer 6730, cellular or mobile phone 6740, or television 6750 (or set-top box coupled to a television). Also illustrated is a smartwatch and health monitoring device 6760. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 6700 may further be used as part of a cloud-based service(s) 6770. For example, the previously mentioned devices, and/or other devices, may access computing resources in the cloud (i.e., remotely located hardware and/or software resources). Still further, system 6700 may be utilized in one or more devices of a home 6780 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 34 is the application of system 6700 to various modes of transportation 6790. For example, system 6700 may be used in the control and/or entertainment systems of aircraft, trains, buses, cars for hire, private automobiles, waterborne vessels from private boats to cruise liners, scooters (for rent or owned), and so on. In various cases, system 6700 may be used to provide automated guidance (e.g., self-driving vehicles), general systems control, and otherwise. These any many other embodiments are possible and are contemplated. It is noted that the devices and applications illustrated in FIG. 34 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation [entity] configured to [perform one or more tasks] is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function,

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement, The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a first vertical transistor formed in a transistor region of an integrated circuit cell structure, the first vertical transistor having a lower source/drain region, a first gate, and an upper source/drain region stacked in a vertical dimension;
a second vertical transistor formed in the transistor region, the second vertical transistor having a lower source/drain region, a second gate, and an upper source/drain region stacked in the vertical dimension, wherein the second vertical transistor is parallel to the first vertical transistor along a first direction in a horizontal dimension with at least some spacing in the first direction between the vertical transistors;
a first metal layer located above the transistor region in the vertical dimension, wherein the first metal layer includes parallel signal routing in the first direction;
at least one gate via coupled between the signal routing in the first metal layer and at least one of the first gate and the second gate; and
a second metal layer located below the transistor region in the vertical dimension, wherein the second metal layer includes parallel power routing in a second direction perpendicular to the first direction in the horizontal dimension.

2. The apparatus of claim 1, wherein the first vertical transistor and the second vertical transistor are complementary transistor types.

3. The apparatus of claim 1, wherein the first vertical transistor is a PMOS transistor, and wherein the second vertical transistor is an NMOS transistor.

4. The apparatus of claim 1, further comprising a gate bridge that extends across the at least some spacing in the first direction between the vertical transistors, wherein the gate bridge is coupled between the first gate and the second gate.

5. The apparatus of claim 4, wherein the at least one gate via is coupled between the signal routing in the first metal layer and a portion of the gate bridge in the at least some spacing between the vertical transistors.

6. The apparatus of claim 5, wherein the at least one gate via is coupled between the gate bridge and a signal input route of the signal routing in the first metal layer.

7. The apparatus of claim 1, further comprising a third metal layer positioned below the lower source/drain regions and above the second metal layer, wherein the third metal layer includes at least one metal portion in contact with at least one of the lower source/drain regions.

8. The apparatus of claim 7, further comprising a lower via coupled between the at least one metal portion in the third metal layer and the power routing in the second metal layer.

9. The apparatus of claim 4, further comprising:
a fourth metal layer positioned above the upper source/drain regions and below the first metal layer, wherein the fourth metal layer includes at least one metal portion in contact with at least one of the upper source/drain regions.

10. The apparatus of claim 9, wherein the fourth metal layer includes:
a first contact coupled to the upper source/drain region of the first transistor, the first contact having a portion extending away from the upper source/drain region in the second direction; and
a second contact coupled to the upper source/drain region of the second transistor, the second contact having a portion extending away from the upper source/drain region in the second direction.

11. The apparatus of claim 10, further comprising:
a first contact via coupled between an end of the first contact distal from the upper source/drain region of the first transistor and a signal output route of the signal routing in the first metal layer; and
a second contact via coupled between an end of the second contact distal from the upper source/drain region of the second transistor and the signal output route.

12. The apparatus of claim 9, further comprising:
a third vertical transistor formed in the transistor region, the third vertical transistor having a lower source/drain region, a third gate, and an upper source/drain region stacked in the vertical dimension, wherein the third vertical transistor is parallel to the first vertical transistor along the second direction;
a fourth vertical transistor formed in the transistor region, the fourth vertical transistor having a lower source/drain region, a fourth gate, and an upper source/drain region stacked in the vertical dimension, wherein the fourth vertical transistor is parallel to the third vertical transistor along the first direction in the horizontal dimension with at least some spacing in the first direction between the third and fourth vertical transistors;
a first contact in the fourth metal layer, wherein the first contact is coupled between the upper source/drain region of the first transistor and the upper source/drain region of the third transistor, the first contact having a portion extending beyond the upper source/drain region of the third transistor in the second direction; and
a second contact in the fourth metal layer, wherein the second contact is coupled between the upper source/drain region of the second transistor and the upper source/drain region of the fourth transistor.

13. The apparatus of claim 12, further comprising:
a first contact via coupled between the portion of the first contact extending beyond the upper source/drain region of the third transistor in the second direction and a signal output route of the signal routing in the first metal layer;
a metal extension portion coupled to a bottom of the lower source/drain region of the fourth transistor, wherein the metal extension portion extends towards a boundary of the integrated circuit cell from the bottom of the lower source/drain region in the second direction; and
a second contact via coupled between the metal extension portion and the signal output route.

14. The apparatus of claim 9, wherein the fourth metal layer includes:
a first contact coupled between the upper source/drain region of the first transistor and the upper source/drain region of the second transistor.

15. The apparatus of claim 14, further comprising:
a third vertical transistor formed in the transistor region, the third vertical transistor having a lower source/drain region, a third gate, and an upper source/drain region stacked in the vertical dimension, wherein the third vertical transistor is parallel to the first vertical transistor along the second direction;
a fourth vertical transistor formed in the transistor region, the fourth vertical transistor having a lower source/drain region, a fourth gate, and an upper source/drain region stacked in the vertical dimension, wherein the fourth vertical transistor is parallel to the third vertical transistor along the first direction in the horizontal dimension with at least some spacing in the first direction between the third and fourth vertical transistors; and
a second contact in the fourth metal layer, wherein the second contact is coupled between the upper source/drain region of the third transistor and the upper source/drain region of the fourth transistor.

16. The apparatus of claim 15, further comprising a third contact coupled between the lower source/drain regions of the first, second, third, and fourth vertical transistors, wherein the first gate, the second gate, the third gate, and the fourth gate include, respectively, a first gate extension, a second gate extension, a third gate extension, and a fourth gate extension, wherein each gate extension extends horizontally at least some distance in the second direction from its respective gate, the apparatus further comprising:
a first gate via coupled between the first gate extension and a first signal input route of the signal routing in the first metal layer, wherein the first gate via is the at least one gate via;
a second gate via coupled between the second gate extension and the first signal input route of the signal routing in the first metal layer;
a third gate via coupled between the third gate extension and a second signal input route of the signal routing in the first metal layer;
a fourth gate via coupled between the fourth gate extension and the second signal input route of the signal routing in the first metal layer; and
a contact via coupled between the third contact and the first signal input route.

17. An apparatus, comprising:
a first vertical transistor formed in a transistor region of an integrated circuit cell structure, the first vertical transistor having a lower source/drain region, a first gate, and an upper source/drain region stacked in a vertical dimension;
a second vertical transistor formed in the transistor region, the second vertical transistor having a lower source/drain region, a second gate, and an upper source/drain region stacked in the vertical dimension, wherein the second vertical transistor is parallel to the first vertical transistor along a first direction in a horizontal dimension with at least some spacing in the first direction between the first and second vertical transistors;
a first metal layer located above the transistor region in the vertical dimension, wherein the first metal layer includes parallel signal routing in the first direction;
a first gate bridge that extends across the at least some spacing in the first direction between the first and second vertical transistors, wherein the first gate bridge is coupled between the first gate and the second gate;
a first gate via coupled between a first signal input route of the signal routing in the first metal layer and the first gate bridge;
a second metal layer located below the transistor region in the vertical dimension, wherein the second metal layer includes parallel power routing in a second direction perpendicular to the first direction in the horizontal dimension;
a third metal layer positioned below the lower source/drain regions and above the second metal layer, wherein the third metal layer includes lower metal contacts coupled to the lower source/drain regions;
lower contact vias between the lower metal contacts and the power routing in the second metal layer;
a fourth metal layer positioned above the upper source/drain regions and below the first metal layer, wherein the fourth metal layer includes upper metal contacts coupled to the upper source/drain regions, the upper metal contacts having portions extending away from the upper source/drain regions in the second direction; and
a first set of upper contact vias coupled between a first signal output route of the signal routing in the first metal layer and the upper metal contacts coupled to the first and second vertical transistors.

18. The apparatus of claim 17, wherein the lower contact vias include:
a first set of lower contact vias coupled between a first power route of the power routing in the second metal layer and a lower metal contact coupled to the first vertical transistor; and
a second set of lower contact vias coupled between a second power route of the power routing in the second metal layer and a lower metal contact coupled to the second vertical transistor.

19. An apparatus, comprising:
a first vertical transistor formed in a transistor region of an integrated circuit cell structure, the first vertical transistor having a lower source/drain region, a first gate, and an upper source/drain region stacked in a vertical dimension;
a second vertical transistor formed in the transistor region, the second vertical transistor having a lower source/drain region, a second gate, and an upper source/drain region stacked in the vertical dimension, wherein the second vertical transistor is parallel to the first vertical transistor along a first direction in a horizontal dimension with at least some spacing in the first direction between the first and second vertical transistors;
a third vertical transistor formed in the transistor region, the third vertical transistor having a lower source/drain region, a third gate, and an upper source/drain region stacked in the vertical dimension, wherein the third vertical transistor is parallel to the first vertical transistor along a second direction perpendicular to the first direction in the horizontal dimension with at least some spacing in the second direction between the first and third vertical transistors;
a fourth vertical transistor formed in the transistor region, the fourth vertical transistor having a lower source/drain region, a fourth gate, and an upper source/drain region stacked in the vertical dimension, wherein the fourth vertical transistor is parallel to the third vertical transistor along the first direction with at least some spacing in the first direction between the third and fourth vertical transistors, and wherein the fourth vertical transistor is parallel to the second vertical transistor along the second direction with at least some spacing in the second direction between the second and fourth vertical transistors; and
a first metal layer located above the transistor region in the vertical dimension, wherein the first metal layer includes parallel signal routing in the first direction;
a first gate bridge that extends across the at least some spacing in the first direction between the first and second vertical transistors, wherein the first gate bridge is coupled between the first gate and the second gate;
a second gate bridge that extends across the at least some spacing in the first direction between the third and fourth vertical transistors, wherein the second gate bridge is coupled between the third gate and the fourth gate;
a first gate via coupled between a first signal input route of the signal routing in the first metal layer and the first gate bridge;
a second gate via coupled between a second signal input route of the signal routing in the first metal layer and the second gate bridge;
a second metal layer located below the transistor region in the vertical dimension, wherein the second metal layer includes parallel power routing in a second direction perpendicular to the first direction in the horizontal dimension;
a third metal layer positioned below the lower source/drain regions and above the second metal layer, wherein the third metal layer includes:
a first lower metal contact coupled to the lower source/drain region of the first vertical transistor;
a second lower metal contact coupled to the lower source/drain region of the second vertical transistor;
a third lower metal contact coupled to the lower source/drain region of the third vertical transistor; and
a fourth lower metal contact coupled to the lower source/drain region of the fourth vertical transistor, wherein the fourth lower metal contact includes a metal extension portion extends from the lower source/drain region towards a boundary of the integrated circuit cell in the second direction;
a fourth metal layer positioned above the upper source/drain regions and below the first metal layer, wherein the fourth metal layer includes:
a first upper contact, wherein the first upper contact is coupled between the upper source/drain region of the first transistor and the upper source/drain region of the third transistor, the first upper contact having a portion extending beyond the upper source/drain region of the third transistor in the second direction; and
a second upper contact in the fourth metal layer, wherein the second upper contact is coupled between the upper source/drain region of the second transistor and the upper source/drain region of the fourth transistor;
a first contact via coupled between the portion of the first upper contact extending beyond the upper source/drain region of the third transistor in the second direction and a signal output route of the signal routing in the first metal layer; and
a second contact via coupled between the metal extension portion of the fourth lower metal contact and the signal output route.

20. An apparatus, comprising:
a first vertical transistor formed in a transistor region of an integrated circuit cell structure, the first vertical transistor having a lower source/drain region, a first gate, and an upper source/drain region stacked in a vertical dimension;
a second vertical transistor formed in the transistor region, the second vertical transistor having a lower source/drain region, a second gate, and an upper source/drain region stacked in the vertical dimension, wherein the second vertical transistor is parallel to the first vertical transistor along a first direction in a horizontal dimension with at least some spacing in the first direction between the first and second vertical transistors;
a third vertical transistor formed in the transistor region, the third vertical transistor having a lower source/drain region, a third gate, and an upper source/drain region stacked in the vertical dimension, wherein the third vertical transistor is parallel to the first vertical transistor along a second direction perpendicular to the first direction in the horizontal dimension with at least some spacing in the second direction between the first and third vertical transistors;
a fourth vertical transistor formed in the transistor region, the fourth vertical transistor having a lower source/drain region, a fourth gate, and an upper source/drain region stacked in the vertical dimension, wherein the fourth vertical transistor is parallel to the third vertical transistor along the first direction with at least some spacing in the first direction between the third and fourth vertical transistors, and wherein the fourth vertical transistor is parallel to the second vertical transistor along the second direction with at least some spacing in the second direction between the second and fourth vertical transistors; and
a first metal layer located above the transistor region in the vertical dimension, wherein the first metal layer includes parallel signal routing in the first direction;
a second metal layer located below the transistor region in the vertical dimension, wherein the second metal layer includes parallel power routing in a second direction perpendicular to the first direction in the horizontal dimension;
a third metal layer positioned below the lower source/drain regions and above the second metal layer, wherein the third metal layer includes a lower metal contact coupled between the lower source/drain regions of the first, second, third, and fourth vertical transistors;
a fourth metal layer positioned above the upper source/drain regions and below the first metal layer, wherein the fourth metal layer includes:
a first upper contact coupled between the upper source/drain region of the first transistor and the upper source/drain region of the second transistor; and
a second upper contact coupled between the upper source/drain region of the third transistor and the upper source/drain region of the fourth transistor;
a first gate extension that extends horizontally at least some distance in the second direction from the first gate;
a second gate extension that extends horizontally at least some distance in the second direction from the second gate;
a third gate extension that extends horizontally at least some distance in the second direction from the third gate;
a fourth gate extension that extends horizontally at least some distance in the second direction from the fourth gate;
a first gate via coupled between the first gate extension and a first signal input route of the signal routing in the first metal layer;
a second gate via coupled between the second gate extension and the first signal input route of the signal routing in the first metal layer;
a third gate via coupled between the third gate extension and a second signal input route of the signal routing in the first metal layer;
a fourth gate via coupled between the fourth gate extension and the second signal input route of the signal routing in the first metal layer; and
a contact via coupled between the lower metal contact and the first signal input route.
